(19) United States
(12) Patent Application Publication
(10) Pub. No.: US 2023/0369525 A1
(43) Pub. Date: Nov. 16, 2023

(54) OPTICAL POWER CONVERTER

(71) Applicant: University College Cork - National University of Ireland,Cork, Cork (IE)

(72) Inventors: Brian Corbett, Cork (IE); Brendan Roycroft, Cork (IE)

(21) Appl. No.: 18/021,798

(22) PCT Filed: Aug. 17, 2021
(86) PCT No.: PCT/EP2021/072816

§ 371 Date: Feb. 16, 2023

(30) Foreign Application Priority Data
Aug. 17, 2020 (GB) 2012813.8

(51) Int. Cl. H01L 31/054; H01L 31/072

(52) U.S. Cl. CPC H01L 31/0543; H01L 31/072

(57) ABSTRACT

An optical power converter device (200, 300) comprises a semiconductor waveguide structure having a first end facet (F1) configured to receive an incident light beam, and one or more light absorbing layers (210a) with a total thickness of substantially less than 100 nm and configured to absorb light guided by the waveguide structure. The device further comprises a cathode (202) and an anode (204) in contact with substantially the entire length of the waveguide structure in the direction of propagation of light from the first end facet for outputting generated electrical power. An optical power converting system (1000) comprising the optical power converter device is also provided, as is a method of operating the optical power converter.

### TECHNICAL FIELD

This invention relates generally to an optical power converter device and method of operation, particularly, but not exclusively, to an optical power converter device comprising a semiconductor waveguide structure.

### BACKGROUND TO THE INVENTION

Optical power converters are a specific type of photovoltaic (PV) device or cell designed for converting high power monochromatic or narrow spectral bandwidth incident light, e.g. produced by a laser or light emitting diode (LED), into electrical power for power-by-light applications. Where laser light is used, such devices are called laser power converters (LPCs). Optical power can be delivered to LPCs through free space or optical fibers over long distances and is an elegant means for powering electrical components and systems in or from remote locations, particularly where a conventional electrical power supply is limited, not available and/or not suitable. For example, optical power delivery is particularly beneficial where there is a need for voltage isolation, high voltage or lightening protection, low noise/electromagnetic interference, and/or spark protection (e.g. when powering sensors in transformer stations, aircraft cockpits or in petrochemical systems). Weight reduction and corrosion resistance is an additional advantage of using optical fibers over copper cables. In addition, remote nodes and photonic integrated circuits for communications and for the Internet of Things can be powered with fiber delivered light where the same fiber can be used to transmit and receive data.

Unlike solar cells, which are designed to convert a broad spectrum of solar light which extends well above the band-gap energy of the absorbing layer(s) leading to significant thermalization losses that limit the conversion efficiency, LPCs can convert light with relatively high efficiency by using monochromatic (laser) light at photon energies at or just above the band-gap edge of the semiconductor absorbing layer(s).

The state of the art conversion efficiencies achieved for LPCs using single p-n junction photovoltaic cells is in the range 55-60 %, where the typical maximum incident power densities for achieving high efficiency in the range 20-50 W/cm², equivalent to 200-500 suns. Most reported results for LPCs are for incident wavelengths around 800 nm using Gallium arsenide (GaAs)-based photovoltaic cells. It is also desirable to operate in the 1300-1600 nm wavelength range to allow powering over longer distances using low loss optical fibers. At 1550 nm, indium gallium arsenide (InGaAs)-based cells have achieved around 43% conversion efficiency at 0.1 W/cm², while GaSb cells achieved around 43% conversion efficiency at 20 W/cm². The maximum output voltage is the open circuit voltage which is determined primarily by the photo-carrier density. Typically, a maximum open circuit voltage of about 1.20 V is obtained for GaAs-based cells, which is significantly lower than the band-gap of GaAs absorbing layer (1.41 eV), indicating power loss. All these cells are limited in the voltage achieved by the device properties at increasing power density where resistive and thermal effects result in a severe reduction in the fill factor of the cell.

Most reported LPCs are configured for top illumination in a similar manner to conventional PV cells and solar cells. For this purpose, a top electrical contact formed of a metal grid or transparent conductive material is used to let incident light reach the underlying semiconductor layers and collect the photo-generated current. However, both approaches lead to transmission/photon and resistive losses. For example, transparent conductive materials are typically more resistive than metals and can absorb certain wavelengths of light, while metal grid contacts lead to a significant shadowing of the incident light and more resistive lateral conduction paths for photo-carriers, which limits the conversion efficiency. The top illumination arrangement is compatible with incident light beams of large cross sectional area that fill the top surface area of the LPC and is most suitable for operation at low current densities. However, it is desirable for an LPC to operate at higher voltages and currents and to be able to convert light at higher efficiencies and incident powers.

Aspects and embodiments of the present invention have been devised with the foregoing in mind.

### SUMMARY OF THE INVENTION

According to a first aspect of the invention there is provided an optical power converter device, for converting optical power in an incident light beam into electrical power (i.e. voltage and current). The incident light beam may be substantially monochromatic, such as a laser beam generated by a laser, or substantially narrowband (e.g. with a full-width at half maximum spectral bandwidth of substantially less than 50 nm), such as a light beam generated by a light emitting diode. The incident light beam may have a centre or peak wavelength and a corresponding photon energy. The centre wavelength may be in the range between substantially 360 nm to 3000 nm. The device may comprise a semiconductor waveguide structure configured to confine and guide light through the device, where it can be absorbed and converted to electrical charge. The waveguide structure may comprise a plurality of semiconductor layers arranged in a growth direction. The plurality of layers may be substantially planar. The growth direction is substantially perpendicular to the plane of the layers. Light confined and guided within the waveguide structure may have a propagation direction substantially parallel to the plane of the layers. The waveguide structure, layers or layer structure may be provided on a substrate. The plurality of layers may form a layer sequence or sequence of layers in the growth direction. The waveguide structure may comprise different regions, where each region comprises one or more semiconductor layers. The device or waveguide structure may comprise a first (or front) end facet for receiving an incident light beam, e.g. in a direction substantially perpendicular to the growth direction. The first end facet may be substantially planar or may be or comprise a substantially planar surface. The first end facet may be or comprise a side of the waveguide structure or device. In this way, the device may be configured for side illumination. Light received or input at the first end facet is guided along the axis of the waveguide in one or more waveguide modes. The waveguide structure may comprise one or more light absorbing layers configured to absorb light guided by the waveguide structure. The one or more light absorbing layers may be thin, having a total thickness (in the growth direction) of substantially less than 100 nm, e.g. between substantially 1 nm and 100 nm. Where there is more than one absorbing layer, adjacent absorbing layers may be separated by a non-absorbing layer. The one or more light absorbing layers may spatially overlap a guided mode of the waveguide structure. Photo-carriers (photo-generated electrons and holes) are generated in the light absorbing layer(s) through absorption of photons in the light beam (or guided mode). The waveguide structure has a length extending from the first end facet in the direction of propagation of light. The waveguide structure may further comprise a cathode and an anode in contact with (and which extend) substantially the entire length of the waveguide structure in the direction of propagation of light from the first end facet for outputting generated electrical power. One of the cathode or anode may be a top electrode which contacts a top or upper surface of the waveguide structure with respect to the growth direction.

A waveguide or waveguide structure is defined as any structure used for guiding light in a (propagation) direction parallel to its axis, confining it in one or more dimensions to a region within or adjacent to its surfaces. A transverse waveguide is formed by a sequence of layers with differing refractive indices, usually comprising an inner or core region of higher refractive index material compared to surrounding/outer or cladding regions. In this context, a transverse waveguide confines light in the growth direction (one dimensional optical confinement). The combination of a transverse waveguide with additional lateral confinement confines light in two directions e.g. to a channel (two dimensional optical confinement).

The growth direction refers to the direction in which the semiconductor layers are grown, e.g. epitaxially, layer by layer in a bottom up fashion. Where there is a substrate, this is the first or bottom layer (in growth order) of the layer structure. The layer structure also comprises a last or top layer having a top surface contacted by the top electrode. Where used herein, the terms “upper”, “lower”, “top” and “bottom” are relative to the growth direction, and the terms “inner”, “outer” are relative to the waveguide core (see below).

The waveguide structure may comprise an n-type cladding region, a p-type cladding region, and a core region between the n-type and p-type cladding regions for confining and guiding light. The core and cladding regions may be referred to as light guiding regions. The n-type cladding region, p-type cladding region, and core region may comprise one or more semiconductor layers. The n-type cladding region, core region and the p-type cladding region may form a transverse (slab) waveguide for confining light (i.e. received at the first end facet) in the growth direction, e.g. to the core region. The dimensions of the core and cladding regions determine which modes can exist, as is known in the art. The transverse waveguide may be configured as a single mode or multi-mode waveguide for the wavelength of incident light.

The transverse (slab) waveguide may confine light to a region localised to and/or near the light absorbing layer(s). The light absorbing layer(s) may be positioned within the spatial extent of a guided mode, preferably the fundamental waveguide mode, of the transverse waveguide. In this way, light received at the first end facet can be absorbed along the/a length of the absorbing layer(s) (in a direction parallel to the plane to the layers and/or perpendicular to the growth direction) as it propagates along the transverse waveguide.

The cathode and anode may be in contact with and/or be electrically connected to (directly or indirectly, e.g. via one or more intermediate layers or regions, such as a contacting layer, as described below) the respective n-type and p-type cladding regions. The n-type cladding region and the p-type cladding region may form a p-n junction for separating photo-carriers generated in the light absorbing layer(s). The cathode may be configured to extract photo-carriers or photo-generated electrons collected by the n-type cladding region, and the anode may be configured to extract photo-carriers or photo-generated holes collected by the p-type cladding region.

In an embodiment, the light absorbing layer(s) is positioned between the n-type and p-type cladding regions, and optionally forms at least part of the core region. In this case, the light absorbing layer(s) may form at least a part of the core region. For example, the light absorbing layer(s) may be positioned within the core region, or form the core region (including any non-absorbing separating layers). Either of the n-type and p-type cladding regions may be positioned above the light absorbing layer(s) relative to the growth direction. Alternatively, the light absorbing layer(s) (including any non-absorbing separating layers) may be positioned within the n-type or p-type cladding region (and still overlap a guided waveguide mode), optionally in proximity to the core region. In this case, the absorbing layer(s) may be positioned between a first and a second n-type or p-type layer of the respective n-type or p-type cladding region.

The optical power converter of the invention has a side illumination (also known as edge-coupled) waveguide configuration. This has several advantages over known top illumination devices that lead to increased conversion efficiency, operation at higher voltages and operation at higher incident power densities.
There is no shadowing or blocking of the incident light beam by the electrodes (typically located at the top and bottom of the layer structure) as there is in a top illumination configuration, which reduces transmission losses.
Metal grid electrodes are not required for the top electrode, allowing resistive losses from transport of photo-carriers to be minimised. In particular, the top electrode can cover the whole top surface of the waveguide structure lowering the contact resistance, and lateral transport of photo-carriers from the absorbing layer(s) to the contacting areas of the top electrode associated with grid electrodes is eliminated because photo-carrier transport is essentially one dimensional in the side illumination configuration.
Absorption of light in an absorbing layer(s) is determined by the material absorption coefficient, the spatial overlap with the waveguide mode and the optical path length of light in the absorbing layer(s). In the side illumination configuration, the optical path length is determined primarily by the length of the absorbing layer(s), not its thickness as in conventional top illumination devices. The length of an absorbing layer(s) (typically > 300 µm, see below) is orders of magnitude greater than its thickness (≤ 100 nm) providing a naturally longer optical path length for absorption, meaning complete absorption of the incident light is possible.
The thin absorbing layer(s) results in higher photo-carrier densities which increases the open circuit voltage.
The thin absorbing layer(s) also leads to reduced loss of photo-carriers by spontaneous emission.
Direct generation of photo-carriers in the absorbing layer(s) within the p-n junction region leads to strong electric fields for photo-carrier separation.
In addition, because light is absorbed in the absorbing layer(s) and not the p- and n-type cladding regions, photo-carriers have a short distance to diffuse/drift to the respective p- and n-type cladding regions to be collected and do not have to cross each other to do so. For example, in a conventional top illumination p-n junction device light is absorbed in the p- and n-type regions including either side of the p-n junction: electrons generated in the p-side need to cross the p-n junction to reach the n-side to be collected, and vice versa for holes generated in the n-side, increasing the collection path length and probability of carrier recombination.
The waveguide structure of the optical power converter can be configured or tailored for operation with the specific wavelength of the incident light beam through choice of the semiconductor materials of the waveguide structure, as is known in the art (see below).

The device may be configured to operate in a photovoltaic mode, e.g. such that a positive voltage is generated between the anode and cathode in use. With at least the features described above, the device may generate an open circuit voltage of at least 90% of the band-gap energy/voltage of the absorbing layer(s) in use.

Each of the plurality of layers of the waveguide structure may be formed of/from a semiconductor material. In this context, a semiconductor material means a compound or alloy, formed of or comprising or consisting of a “combination” of two or more elements in a particular ratio or composition. For example, the semiconductor material may be a binary compound (formed of two elements), a ternary compound (formed of three elements), a quaternary compound (formed of four elements), etc. The semiconductor material has a “composition” defined by the relative fraction of each element in the compound. For example, a ternary compound comprising elements A, B and C may be expressed as AₓB₁₋ₓC where x is the composition parameter indicating the mole fraction of element A ranging from 0 to 1. The composition of the compound AₓB₁₋ₓC can be varied from BC (x=0) to AC (x=1) by varying the composition parameter. A ternary compound has one composition parameter x, while a quaternary compound has two composition parameters x and y, as is known the art. The combination of elements and their composition determine the optical properties of the semiconductor material, such as band-gap energy and refractive index. The dependence of band-gap energy and refractive index on material composition (and temperature) of a given compound is well known in the art. A semiconductor material may further include a dopant material to make it n-type or p-type, as is known in the art. N-type and p-type refers to the majority charge carriers being electrons or holes, respectively.

In an embodiment, the semiconductor materials of the layers are direct band-gap semiconductor materials. The semiconductor materials may be III-V semiconductor materials consisting of or comprising elements selected from groups III and V of the periodic table, such as aluminium (Al), gallium (Ga), indium (In), boron (B), phosphorous (P), arsenic (As), antimony (Sb), nitrogen (N), and bismuth (Bi). Alternatively, the semiconductor materials of the layers may be II-VI semiconductor materials consisting of or comprising elements selected from groups II and VI of the periodic table, such as cadmium (Cd), zinc (Zn),, beryllium (Be), magnesium (Mg), sulphur (S), selenium (Se) and tellurium (Te), oxygen (O).

The light absorbing layer(s), core region, n-type and p-type cladding regions, and optionally any other layers, may be provided on the substrate. Alternatively, one of the n-type and p-type cladding regions may be or include the substrate. The substrate may be formed of or comprise a III-V semiconductor material (as defined above) such as gallium arsenide (GaAs), gallium antimonide (GaSb), indium phosphide (InP), gallium phosphide (GaP), or gallium nitride (GaN), or indium arsenide (InAs), or any other suitable III-V semiconductor. Alternatively, the substrate may be formed of or comprise silicon (Si), or sapphire, or germanium (Ge), or silicon carbide (SiC). The substrate may be doped or un-doped (semi-insulating). Where present and when doped, one of the cathode or anode (whichever is not the top electrode) may electrically contact the substrate.

The light absorbing layer(s) may be formed of a semiconductor material having a band-gap energy substantially less than or equal to the photon energy of the incident light so as to absorb the incident light. In an embodiment, the band-gap energy of the light absorbing layer(s) is at most 300 meV less than the photon energy of the incident light, and preferably at most 100 meV, 70 meV, or 50 meV less than the photon energy of the incident light. The core and cladding regions may be formed of a semiconductor material having a band-gap energy substantially greater than the photon energy of the incident light. In this way, such regions are substantially transparent to the incident light, and light is only absorbed in the light absorbing layer(s). The light absorbing layer(s) may be formed of or comprise a semiconductor material having a band-gap energy and/or refractive index substantially lower and/or higher, respectively, than that of the n-type, core and p-type cladding regions.

The device may be configured to operate with an incident light beam having a centre wavelength in the range between substantially 360 nm and 3000 nm (e.g. 360 nm to 600 nm, or 600 nm to 1300 nm, or 1100 nm to 2000 nm, or 1500 nm to 3000 nm) by appropriate choice of semiconductor materials for the absorbing layer(s) and guiding regions.

GaN-based materials can be used for converting light in the 360 nm to 600 nm range. GaAs-based materials can be used for converting light in the 600 nm to 1300 nm wavelength range. InP-based materials can be used for converting light in the 1100 nm to 2000 nm range. GaSb-based materials can be used for converting light in the 1500 nm to 3000 nm wavelength range. GaN-based materials include, but are not limited to: GaN, AlGaN, GaNAs, InGaN, and AlInN. GaAs-based materials include but are not limited to: GaAs, InGaAs, AlGaAs, AlAs, AlGaInP, GaAsSb, InAlAs, AlInGaAs. InP-based materials include but are not limited to: InP, InPAs, InPSb, InGaAs,InGaAsP, AlInGaAs, InAlAsP, InAlPSb. GaSb-based materials include, but are not limited to: GaSb, InSb, InAs, AlGaInSb, AlGaInAsSb, and/or AlAsSb.

In an embodiment, the light absorbing layer(s) is(are) formed of or comprise InGaAsP (InₓGa_{1- x}As_{y}P_{1-y}). InGaAsP has a band-gap energy in the range of substantially between 0.565 to 1.2 eV (1050 to 2200 nm) at 300 K depending on the composition parameter x (i.e. In fraction) when formed on an InP substrate. The specific composition is chosen based on the wavelength of the incident light beam (see above).

In an embodiment, the light absorbing layer(s) is(are) formed of or comprise AlInGaAs (AlₓIn_{1-x-y}Ga_{y}As). AlInGaAs has a band-gap energy in the range of substantially between 0.73 to 1.48 eV (840 to 1700 nm) at 300 K depending on the composition parameter x and y (i.e. Al/Ga ratio and In fraction) when formed on an InP substrate. The specific composition is chosen based on the wavelength of the incident light beam (see above).

In another embodiment, the light absorbing layer(s) is(are) formed of or comprise InGaN (InₓGa₁₋ₓN). InGaN has a band-gap energy in the range of substantially between 0.69 to 3.4 eV (360 to 1800 nm) at 300 K depending on the composition parameter x (i.e. In fraction). The specific composition is chosen based on the wavelength of the incident light beam (see above).

In another embodiment, the light absorbing layer(s) is(are) formed of or comprise (AlₓGa_{1- x})In_{y}P. AlGaInP has a band-gap energy in the range of substantially between 1.8 to 2.5 eV (500 to 690 nm) at 300 K depending on the composition parameter x when the alloy is lattice matched to GaAs. The specific composition is chosen based on the wavelength of the incident light beam (see above).

In another embodiment, the light absorbing layer(s) is(are) formed of or comprise InₓGa₁₋ₓAs. InGaAs has a band-gap energy in the range of substantially between 0.96 to 1.44 eV (860 to 1300 nm) at 300 K depending on the composition parameter x when the alloy is compressively strained on GaAs substrates. The specific composition is chosen based on the wavelength of the incident light beam (see above).

The light absorbing layer(s) may be formed of a semiconductor material that is the same or different to at least one of the n-type and p-type cladding regions. Where the semiconductor material is the same, the composition of the absorbing layer(s) is different to that of the at least one n-type and p-type cladding regions.

The n-type and p-type cladding regions may be formed of or comprise one or more n-type and p-type semiconductor materials, respectively, e.g. as described above but doped to be n- or p-type. The semiconductor material(s) of the n-type and p-type cladding regions may be the same or different. Where it is the same, the composition may be the same or different. The thickness, refractive index, and/or band-gap energy of the n-type and p-type cladding regions may be the same or different. The thickness of the n-type and p-type cladding regions may be greater than the thickness of the light absorbing layer(s).

The core region has a refractive index substantially higher than that of the n-type and p-type cladding regions, e.g. at least 1-5 % higher. The semiconductor material of the core region may be the same or different to that of the n-type and/or p-type cladding regions. Where it is the same, the composition is different. The core region may be doped (e.g. comprising one or more n and/or p-type layers) or un-doped or compensation doped (i.e. intrinsic).

The waveguide structure may have a width in a direction perpendicular to the growth direction and to the direction of light propagation (the waveguide axis). The waveguide structure may be configured to provide lateral confinement for confining light in a direction substantially perpendicular to the growth direction. The lateral confinement may define a lateral width of the guided waveguide mode. The lateral confinement may be provided by the top contact and/or a ridge in the waveguide structure (e.g. formed by an etching process), or a buried waveguide (e.g. formed by an etching and redeposition process, as is known in the art). The top contact may be provided as a strip having a width that at least partially defines the width of the fundamental mode of the waveguide structure, and/or having a width that extends, at least partially or fully, across the lateral width of the waveguide structure. Alternatively or additionally, the waveguide structure may comprise a ridge having a width that defines the lateral width of the fundamental mode of the waveguide structure. Optionally or preferably, the top contact (anode or cathode) extends at least partially, and optionally fully, across the width of the ridge. The ridge may be formed in a top surface of the waveguide structure with respect to the growth direction.

Lateral confinement can be used to shape the transverse waveguide mode to more closely match the shape of the incident light beam (e.g. which may have a quasi-circular or elliptical cross-section) so as to more efficiently couple the light into the transverse waveguide.

The length of the waveguide structure may at least partially define the optical path length or propagation length in the light absorbing layer(s). In some cases, the optical path length can be greater than the length of the waveguide structure, where light is reflected back from the end or second end facet of the waveguide structure (see below). In an embodiment, the waveguide structure may extend from the first end facet for a length greater than substantially 300 µm, 400 µm, 500 µm, 600 µm, 700 µm, or 800 µm in the direction of propagation of light from the first end facet. The length of the waveguide structure may be in the range of substantially between 300 µm and 5 mm, or between 300 µm and 1 cm. The length of the waveguide structure may be substantially greater than the absorption length in the absorption layer(s) for the wavelength of the incident light. For example, the absorption length is typically less than 300 µm for most semiconductor materials and waveguide configurations.

The top contact or ridge may have a width in the range of between substantially 2 to 500 µm, e.g. 5 to 500 µm, or 10 to 500 µm, or 20 to 500 µm, or 30 to 500 µm, or 40 to 500 µm, or 50 to 500 µm, or 2 to 100 µm, or 2 to 200 µm, or 2 to 300 µm, or 2 to 400 µm, or any combination or sub-combination of said ranges. The top contact or ridge may have a width that is substantially constant along its length. Alternatively, the top contact or ridge may have a width that varies or tapers along at least a portion of its length.

The light intensity in the absorbing layer(s) decays exponentially with distance from the first end facet, i.e. the most absorption occurs at or near the first end facet. If light is absorbed mostly in the front portion of the waveguide near the first end facet a local voltage with a local photocurrent is generated. Arranging the anode and cathode to contact the entire length of the waveguide advantageously distributes the generated voltage along the entire length (and optionally the entire width width) of the waveguide structure, transverse waveguide and/or waveguide mode. This is because the electrodes make the contacting surface of the device an equipotential surface, and because this extends the length (and optionally width) of the device, the local voltage is immediately (within the resistance*capacitance time constant of the device) redistributed along the length of the device, along with the extracted power. The voltage re-distribution by the electrodes, particularly by the top electrode, therefore avoids the photocurrent being concentrated over a short length/portion of the device which would otherwise increase the device resistance.

This voltage re-distribution also allows the area (i.e. length and width) of the top electrode to be configured/chosen according to the expected input optical power so as to achieve a particular photo-carrier density for optimum power conversion. That is, the area can be used to set the operating point of the device for a given incident light beam. For example, a rough rule of thumb is that the photo-carrier density generated by the incident light beam should equal the transparency carrier density at maximum input power, i.e. in open circuit conditions, which is approximately 1-2 ×10¹⁸ cm⁻³. The area of the top electrode can be designed to achieve this condition by virtue of the voltage re-distribution.

In an embodiment, the top electrode is configured with a predefined area to generate a predefined photo-carrier density in open circuit conditions for a given optical power of the incident light beam. The predefined photo-carrier density may be in the range of substantially 0.5-2 ×10¹⁸ cm⁻³.

The top electrode may be configured to re-distribute the generated photovoltage and/or photo current along substantially the entire length (and optionally width) of the waveguide structure or waveguide mode. The width of the top electrode may substantially match, define, or at least equal, the width of the waveguide mode and/or incident light beam, as explained above. The top electrode may extend at least partially or substantially the entire width of the waveguide structure (or waveguide mode). In this way, generated voltage is re-distributed over the length and width of the waveguide where photo-current is generated, further reducing the contact resistance of the top electrode and resistive losses.

The waveguide structure may further comprise a second end facet, optionally arranged substantially opposite the first end facet. The second end facet may be substantially planar or may be or comprise a substantially planar surface.

The top contact or ridge may extend between the first and second end facets. The width of the top contact or ridge may be constant along its length or vary along its length. The width of the top contact or ridge may taper out towards to the first end facet and/or towards the second end facet. In an embodiment, the top contact or ridge tapers out/widens towards the first end facet to compensate for higher absorption in that region. This may reduce the local photo-carrier density in that tapered region.

The cathode and anode may be formed of or comprise a metal, metal alloy or metallic material. For example, the anode and cathode may be formed from one or more of gold (Au), platinum (Pt), titanium (Ti), chrome (Cr), nickel (Ni), germanium (Ge), palladium (Pd), aluminium (Al), silver (Ag), copper (Cu), titanium nitride (TiN), molybdenum (Mo), conductive polymers etc. The anode and cathode may be formed of or comprise the same or different material or combination of materials.

The cathode and anode are preferably low resistance (e.g. less than 2 Ω or 1 mΩ) for both the electrical connection to the device (to make an Ohmic contact) and the collection of the current/voltage. The connection resistance and thermal resistance can be reduced by electroplating a thick metal layer on the electrodes, e.g. an at least 2 µm or 20 µm thick metal layer formed from one or more, or one or more sub-layers, of Au, Ag, Cu, Ni or Pt.

The waveguide structure may be configured as a single clad or double clad waveguide structure. A double clad structure may comprise an inner (first) and an outer (second) transverse waveguide, with respect to the core region. Where the waveguide structure is configured as a double clad waveguide structure, at least one of the n-type and p-type cladding regions comprises an inner (first) and an outer (second) cladding layer or sub-region, with respect to the core region, to provide a respective inner (first) and outer (second) transverse waveguide. The inner cladding layer(s)/sub-region(s) is/are adjacent the core region, and the outer cladding layer(s)/sub-region(s) is/are adjacent the respective inner cladding layer(s)/sub-region(s) (i.e. further away from the core region than the inner cladding layers(s)/sub-region(s)).

The outer n-type cladding layer/sub-region may be positioned between the cathode and the inner n-type cladding layer/sub-region. The outer p-type cladding layer/sub-region may be positioned between the anode and the inner p-type cladding layer/sub-region. The outer n-type and/or p-type cladding layer(s)/sub-region(s) may form at least part of the outer (second) transverse waveguide. The outer (second) transverse waveguide may confine light in the growth direction to a region including the inner n-type and p-type cladding layers/sub-regions and the core region.

Because the outer (second) transverse waveguide is wider (in the growth direction) than the inner (first) transverse waveguide, the double clad structure/second transverse waveguide allows a wider width light beam to couple into the device compared to a single clad structure. For example, a single-clad waveguide structure may be limited to light beams with a width at the first end facet on the order of a few microns (e.g. on the order of the width/thickness of the core region), while a double-clad structure may allow light beams with a width at the first end facet on the order of tens of microns to be used (e.g. on the order of the combined width/thickness of the core and inner cladding regions). Using a wider light beam advantageously allows a higher power incident light beam to be used (in terms of Watts) compared to a single clad structure without damaging the first end facet, allowing more light to be coupled into and/or absorbed in the light absorbing layer(s), increasing the generated electrical power. This is because the maximum incident power (in terms of Watts) of a light beam incident on the first end facet is limited by the damage threshold power density (in terms of Watts/cm²) for the first end facet, which is typically around 10 MW/cm² for most semiconductor materials. For example, the maximum incident power for a typical single-clad waveguide structure may be on the order 200-300 mW, while the maximum incident power for a typical double-clad waveguide structure may be on the order 1-10 W. In use, light in the (wider) light beam incident on the first end facet couples into or is collected by the outer (second) transverse waveguide, and then couples into the inner (first) transverse waveguide as it propagates. The outer (second) transverse waveguide may be configured as a multi-mode waveguide for the wavelength of incident light.

In this context, a high incident power light beam may be on the order of 0.1-10 Watts or greater.

The outer n-type and p-type cladding layers may be formed of or comprise a semiconductor material with a band-gap energy/refractive index substantially higher/lower than that of the respective inner n-type and p-type cladding layers. The refractive index, band-gap energy, and/or thickness of the outer n-type and p-type cladding layers may be the same or different. The thickness of the outer n-type and p-type cladding layers may be greater than the thickness of the light absorbing layer(s) and/or the inner n-type and p-type cladding layers.

Where the semiconductor layer structure forms a double clad waveguide structure with inner and outer cladding layers/sub-regions, the inner cladding layers may be un-doped.

The light absorbing layer(s) may be or comprise one or more quantum wells and/or layers of quantum dots. A quantum well is defined as a semiconductor layer having a thickness in the growth direction that is less than or equal to a threshold thickness required to exhibit quantum confinement in the growth direction and discrete energy subbands (typically less than about 15-20 nm thick). A quantum dot is a semiconductor particle having a size in all dimensions that is less than or equal to a threshold thickness required to exhibit quantum confinement and discrete energy subbands. Quantum wells and dots allow the selection of the band-gap energy or absorption spectrum/edge of the absorbing layer(s) through the semiconductor material/compound selected, and through their respective layer thickness or size during growth. Semiconductor materials with a substantially different lattice constant to the rest of the layer structure can be used because they can be strained to match the lattice constant of the surround medium.

The one or more quantum wells and/or layers of quantum dots may be formed of or comprise a semiconductor material having a band-gap energy at least substantially 50 meV lower than the photon energy of the incident light beam. Quantum wells exhibit polarization dependent absorption for photon energies close to the band-gap energy. Engineering an offset between the quantum well band-edge and the incident photon removes any polarization dependence in the quantum well absorption spectrum, allowing polarised light beams to be used without effecting power conversion. Alternatively, quantum wells with compensating absorption spectra (i.e. TE and TM) can be used.

The spatial overlap (Γ) of the light absorbing layer(s) with a waveguide mode (preferably the fundamental mode) of the first transverse waveguide may be in the range of substantially less than 10 %, or less than 1 %, or less than 0.1 %, or less than 0.01 %, e.g. between 0.001 and 10 %, or between 0.01 and 10 %, or between 0.1 and 10 %. The inner n-type and p-type cladding layers may be configured to provide a transverse waveguide mode having the above mentioned spatial overlap Γ with the light absorbing layer(s).

Controlling the spatial overlap of the transverse waveguide mode controls the absorption of the light in the absorbing layer(s), since this is determined at least in part by the material absorption coefficient of the absorbing layer(s) multiplied by the spatial overlap. Having a relatively low spatial overlap (e.g. < 10%, as defined above) means that absorption in the absorbing layer(s) is relatively weak and the absorption length (defined as the propagation length in the absorbing layer(s) at which the light intensity drops by a factor e = 2.7182) is relatively long, e.g. > 10 µm. However, complete absorption is still achievable in the device because the length of the waveguide structure and thus propagation length in the device is relatively long (e.g. > 300 µm) compared to the absorption length in the absorbing layer(s) (see above). Advantageously, controlling the absorption to be weaker allows higher incident powers to be used with the device to efficiently convert more power, compared to if the overlap were higher (e.g. > 10 %). For example, if the spatial overlap is high (e.g. > 10%), the local absorption near the first end facet results in the current being collected through a small area/portion of the device with a corresponding increase in resistive loss in power collection. By controlling the overlap to be relatively low, i.e. < 10% as above, saturation effects in the device at high incident powers (e.g. > 0.1 Watts), particularly near the first end facet where the light intensity is highest, can be avoided.

The plane of the second end facet may be arranged substantially parallel to the growth direction. The plane of the first end facet may be arranged substantially parallel to the growth direction. Alternatively, the plane of the first end facet may be arranged at an angle to the growth direction, so as to prevent feedback to the source of the light beam. For example, the plane of the first end facet may be arranged at an angle substantially between 0-8 degrees to the growth direction, or preferably 0-4 degrees or 0-2 degrees to the growth direction.

The second end facet may comprise a high reflectance coating for the wavelength of the incident light beam. For example, the high reflectance coating may be or comprise a metal mirror coating or a layered dielectric coating, as is known in the art. For example, a quarter wave layer of dielectric (e.g. SiO₂) and metal (e.g. Au), or a quarter wave stack comprising several (e.g. 5) alternating layers of low and high refractive index dielectrics (e.g. SiO₂/TiO₂). Here, quarter wave means a thickness of approximately λ/4n where n is the refractive index and λ is the wavelength of light. The high reflectance coating may be configured to have a reflectance of greater than 90% for the wavelength of the incident light beam. This may reflect/direct any light not absorbed by the absorbing layer(s) on the first pass of the waveguide back towards the first end facet, thereby increasing the optical path length in the waveguide and the overall absorption and conversion efficiency.

The first end facet may comprise a coating configured to reduce the reflectance of the first end facet for the wavelength of the incident light beam. For example, the coating may be or comprise a layered dielectric coating (i.e. comprising one or more layers) configured such that reflections from the surfaces of the layer(s) produce destructive interference for the incident wavelength, as is known in the art (e.g. a quarter wave thick layer of dielectric, such as SiN or SiO₂). Optionally or preferably, the coating is configured to reduce the reflectance of the first end facet to less than 10% for the wavelength of the incident light beam. This may increase the transmission of incident light into the device and thereby the conversion efficiency. The coating may also help reduce material damage at the first end facet at high incident powers. The coating may further be configured to be highly reflective for the wavelength of any light emitted from the light absorbing layer(s) (e.g. from spontaneous emission) so as to recycle the generated light energy.

The first end facet may also be treated so as to have a higher bandgap or lower refractive index by using a post-growth surface modification technique, such as impurity induced intermixing, as is known in the art.

The device may comprise a lens or prism for coupling the light beam into the waveguide structure within its angle of acceptance or its etendue (waveguide area * (refractive index*acceptance angle)²). The lens or prism may be coupled/attached to the first end facet. Alternatively or additionally, the first end facet may comprise a grating for coupling incident light into the waveguide structure. The grating may be integral with the first end facet, e.g. formed using a post-growth surface modification technique, as mentioned above.

The composition of the semiconductor material of one or more of the cladding regions/layers may be graded, at least over a portion of the thickness of the respective layer/region (e.g. at or in the vicinity of the heterointerfaces). Grading the composition may vary the band-gap energy and/or refractive index over the extent of the grading. This may advantageously assist in photo-carrier extraction to the cathode and/or anode. The grading may be over a thickness of substantially between 20 nm and 50 nm.

The position of the light absorbing layer(s) and/or core region in the waveguide structure may be offset towards the anode to reduce the transport distance for photo-generated holes.

The waveguide structure may comprise or consist of a series of (epitaxially) stacked p-n junctions each containing or a thin absorbing layer, i.e. at least one of the one or more light absorbing layers. Each p-n junction may contain one or more quantum wells and/or layers of quantum dots. Each p-n junction of the series may be connected/separated by a low resistance tunnel junction/diode. The one or more light absorbing layers may comprise the series of (epitaxially) stacked p-n junctions. The number of stacked p-n junctions may be in the range of 2-5 or 2-10. The series of p-n junctions may be positioned between the n-type and p-type cladding region, and optionally within the core region of the waveguide structure. In this case the transverse waveguide may form a single multimode waveguide. Additionally or alternatively, where the layer structure of the n-type cladding layer, the core region, the absorbing layer(s) and the p-type cladding region form a p-n junction containing the absorbing layer(s), this layer structure/sequence may be repeated in the growth direction to form the series of stacked p-n junctions. In this case, the waveguide structure may contain a separate transverse waveguide (which may be single mode) for each p-n junction. Further, in this case the cathode and anode are electrically connected to the respective outer-most (with respect to the growth direction) n-type and p-type cladding regions of the waveguide structure.

Under edge or side illumination, the resultant series connection of p-n junctions (i.e. diodes) will result in a summation of the voltage of each of the number of p-n junctions and a reduction in current by the corresponding number. This permits the delivery of higher voltages to the system.

The waveguide structure may further comprise a p-type and/or n-type contacting layer for electrically contacting the waveguide structure to the respective anode and/or cathode. The anode/cathode may electrically contact the p-type/n-type contacting layer. The p-type/n-type contacting layer may be configured to reduce the contact resistance of the anode/cathode to the semiconductor layer structure, as is known in the art. The p-type/n-type contact layer may be formed of comprise a p-type/n-type semiconductor material having a higher doping density/concentration and/or lower band-gap energy than that of the respective p-type/n-type cladding regions. The p-type/n-type contact layer may have a thickness less than that of the respective p-type/n-type cladding regions.

The device may comprise an array of said waveguide structures. The array of waveguide structures may be arranged substantially in parallel on a substrate. The substrate may be un-doped or semi-insulating. Each waveguide structure may have a respective anode and cathode. The respective anodes and cathodes may be electrically connected in series or in parallel. Each waveguide structure and associated anode and cathode may be referred to as an optical power converter cell or sub-device. The first end facet of each cell may be arranged to receive a separate incident light beam. Connecting multiple optical power converter cells in series or in parallel may advantageously increase the total generated voltage or current, respectively. Features of the waveguide structure and anode/cathode described above (e.g. materials, dimensions, properties, etc.) apply equally to each waveguide structure in the array.

Due to the reciprocal nature of absorption and emission, the optical power converter device described above may be configured or engineered to emit light under certain incident optical powers (e.g. where the incident power is sufficient to overcome losses associated with absorption). This light emission can either be by spontaneous emission as in a light emitting diode, or if the waveguide is provided with high enough incident optical power, stimulated emission where the device can function as an optically pumped laser. The emitted light from the device can be modulated (e.g. by applying a bias to the electrodes) to transmit information back to the source. Since the emitted wavelength of the optically pumped laser is down-converted from the pump/incident wavelength, the emitted light (signal) can be separated from the pump/incident light at the source/receiving end. This allows both remotely powering and communicating of remote devices. In such applications, the optical power converter device can both convert the incident (pump) light beam to power a remote device/electronic component and generate an optical signal (through modulated light emission) to send information back from the it. This has advantages in confined spaces, one such application being at the distal end of an endoscope where a camera could be located and powered by the optical power converter device. This provides a significant advantage in compactness as a single fibre and a single device can provide the channel for both the powering and the signalling.

According to a second aspect of the invention, there is provided an optical power converting system comprising an optical power converter device according to the first aspect. The system may comprise a coupling arrangement for coupling, directing or delivering an incident light beam to the first end facet or waveguide structure of the device, e.g. in a direction substantially perpendicular to the growth direction. The cathode and anode of the device may be connectable to an electrical component for providing electrical power to the electrical component and/or for receiving the electrical power output of the power converter device. The system may comprise the electrical component to be powered, and the cathode and anode of the device may be connected to the electrical component. The electrical component may be provided or integrated on the same substrate as the semiconductor layer structure of the optical converter device.

The coupling arrangement may comprise an optical fiber and/or optical waveguide for guiding the light beam from a source to the system. Alternatively, the light beam may be delivered to the system from a source via free-space.

The coupling arrangement may comprise a lens for receiving an incident light beam and coupling the incident light beam to the first or second transverse waveguide.

The system may comprise a cooling arrangement for removing heat (e.g. generated from unconverted optical energy) from the device. The cooling arrangement may be a passive cooling system, e.g. comprising a heat sink in thermal contact with the device. The heat sink may be coupled directly or indirectly to the anode or cathode.

According to a third aspect of the invention, there is provided a photonic integrated circuit comprising an optical power converter device according to the first aspect for providing electrical power to the photonic integrated circuit. The photonic integrated circuit may comprise one or more electronic components or devices that require electrical power to operate. The photonic integrated circuit may be a silicon, germanium, III-V or II-VI semiconductor based photonic circuit.

The photonic circuit may comprise one or more optical waveguides for receiving an incident light beam (e.g. from an optical fiber) and/or guiding light through the photonic circuit. The optical power converter device may be arranged to receive light guided by an optical waveguide of the photonic circuit and convert the light into electrical power for the photonic circuit. Alternatively or additionally, the optical power converter device may be arranged to receive a light beam from an external light source (e.g. from an optical fiber) and convert the light into electrical power for the photonic circuit.

Photonic integrated circuits are connected, in use, to an optical fibre and typically operate at wavelengths of light that are longer than 1200 nm (e.g. 1300 nm, 1550 nm). According to this aspect, that fiber or a separate one can deliver optical power that can be converted into electrical power by the power converter device and so the circuit itself does not need a separate electrical connection.

According to a fourth aspect of the invention, there is provided a method of operating the optical power converter of the first aspect. The method may comprise coupling an incident light beam into the waveguide structure. The method may further comprise converting the guided light into an electrical power output signal provided at the cathode and anode. The method may further comprise absorbing the guided light to generate photocarriers and an associated photovoltage. The method may further comprise separating the photocarriers at a p-n junction formed by respective p- and n-type cladding regions to generate the photovoltage. The method may further comprise re-distributing the generated photocarriers and photovoltage over the length of the device. The method may further comprise extracting photocarriers at the cathode and anode to generate an electrical power output signal.

The method may further comprise generating an optical output signal from the recombination of the generated photocarriers within the waveguide structure. The optical output signal may be generated from stimulated or spontaneous emission. This may comprise coupling an incident light beam into the waveguide structure with a sufficiently high optical power, e.g. above a threshold incident power for light emission or lasing where optical gain in the device exceeds losses associated with absorption. The method may further comprise modulating the optical output signal to transmit optical information from the device. Modulating the optical output signal may comprise applying a modulated bias to the anode and/or cathode. Optionally or preferably, the optical output signal is modulated using the generated electrical power output signal.

Features which are described in the context of separate aspects and embodiments of the invention may be used together and/or be interchangeable. Similarly, where features are, for brevity, described in the context of a single embodiment, these may also be provided separately or in any suitable sub-combination. Features described in connection with the device may have corresponding features definable with respect to a method, and these embodiments are specifically envisaged.

### BRIEF DESCRIPTION OF DRAWINGS

In order that the invention can be well understood, embodiments will now be discussed by way of example only with reference to the accompanying drawings, in which:

FIG. 1 shows a schematic layer structure of a conventional top illumination optical power converter device;

FIG. 2 shows a schematic illustration conventional top illumination optical power converter device;

FIG. 3a shows a schematic layer structure of an optical power converter device according to an embodiment of the invention;

FIG. 3b shows a layer structure of the absorbing region of FIG. 3a according to an embodiment of the invention;

FIG. 3c shows a layer structure of the absorbing region of FIG. 3a according to another embodiment of the invention;

FIG. 4 shows a schematic illustration of an optical power converter device according to an embodiment of the invention;

FIG. 5 shows an example cross-section of the device of FIG. 4;

FIG. 6 shows the device of FIG. 4 including a lateral waveguide;

FIGS. 7 to 9 show a top view of the device of FIG. 6 with different shaped lateral waveguides;

FIG. 10 shows a schematic layer structure of an optical power converter device according to another embodiment of the invention;

FIGS. 11a and 11b show multiple devices connected in series and parallel, respectively;

FIG. 11c shows an example of multiple sub-devices connected in series;

FIG. 12 shows a schematic illustration of an optical power converter system according to an embodiment of the invention;

FIG. 13a shows a schematic layer structure of an optical power converter device according to another embodiment of the invention;

FIG. 13b shows a schematic layer structure of the absorbing region of FIG. 13a;

FIGS. 14a and 14b show example energy band diagrams of the device of FIG. 13a;

FIG. 15 shows a schematic layer structure of an optical power converter device according to another embodiment of the invention;

FIG. 16 shows light induced current and voltage characteristics of the device of FIG. 15;

FIG. 17 shows a schematic layer structure of an optical power converter device according to another embodiment of the invention; and

FIGS. 18a and 18b show example energy band diagrams of the device of FIG. 17.

It should be noted that the figures are diagrammatic and may not be drawn to scale. Relative dimensions and proportions of parts of these figures may have been shown exaggerated or reduced in size, for the sake of clarity and convenience in the drawings. The same reference signs are generally used to refer to corresponding or similar features in modified and/or different embodiments.

### DETAILED DESCRIPTION

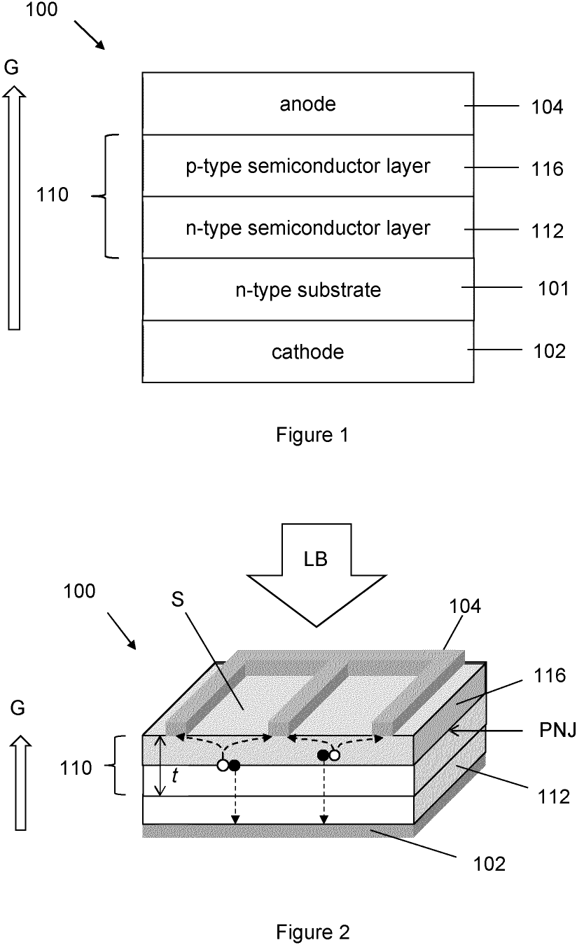

FIGS. 1 and 2 show a conventional photovoltaic (PV) optical power converter device 100 configured for top-illumination. The device 100 comprises a sequence of semiconductors layers in the growth direction G comprising, in order, an n-type substrate 101, and an n-type semiconductor layer 112 and a p-type semiconductor layer 116. The n- and p-type layers 112, 116 form a p-n junction (PNJ) and provide the absorbing region 110. The absorbing region 110 is thick to increase the light absorption, with a thickness t typically in the range 2-4 µm. An n-side electrode (cathode) 102 is provided in electrical contact with the n-type layer 112 (via the substrate 101) and a p-side electrode (anode) is provided in electrical contact with the p-type layer 114 for collecting/extracting the photo-generated electrons and holes, respectively. In this example, the anode 104 is the top electrode (with respect to the growth direction G) and takes the form of a metal grid to permit transmission of incident light through to the underlying absorbing region 110. If a p-type substrate is used, the PNJ is reversed and the cathode is the top electrode (not shown). Some variants of the device 100 comprise an intrinsic region between the n-type and p-type layers 112, 114 which may contain a large number of quantum wells (QWs) that act as an additional absorber (not shown).

In use, a light beam LB with a photon energy (Eₚₕ) at or just above the band-gap energy (E_{g}) of the n- and p-type layers 112, 116 of the absorbing region 110 is incident normal to the top surface S of the device 100 (i.e. parallel to the growth direction G). Incident light is transmitted through the metal grid 104 to the underlying semiconductor layers where it is absorbed in the absorbing region 110 generating electron-hole pairs (photo-carriers). The electron-hole pairs are separated by the PNJ and move (via drift and diffusion) towards the respective cathode and anode 102, 104 at opposite sides of the PNJ where they are collected, thereby generating electrical power.

Several factors can affect the optical to electrical energy conversion efficiency (referred to hereafter as conversion efficiency) of an optical power converter device (and PV devices in general). These include, but are not limited to, transmission losses at the light receiving surface, incomplete absorption in the absorbing region, carrier recombination losses, thermal losses, and resistive losses in the electrodes and/or in the semiconductor layers.

For maximum conversion efficiency, all incident photons should be absorbed and the photo-carriers collected/extracted with minimal resistance, with each photon delivering the photon energy (Eₚₕ). The top-illumination configuration of the device 100 suffers from inherent optical/photon losses due to the shadowing effect of the top electrode 104 and incomplete absorption of light in the absorber 110 due to the limited optical path length in the absorbing region 110, and as well as inefficient photo-carrier extraction at high incident powers due to the lateral transport of photo-generated holes (or electrons if a p-type substrate is used) from the PNJ to the contacting areas of the metal grid electrode 104. Example transport paths of photo-generated electrons (solid circles) and holes (open circles) in the device 100 are indicated by the dashed arrows in FIG. 2. In PV devices, photo-carriers are considered collected once they become majority carriers, i.e. when photo-generated electrons reach the n-type layer 116 and holes reach the p-type layer 112. In the device 100, photo-carriers are generated throughout the thickness of the n-type or p-type layers 112, 116 of the absorbing region 110 and must therefore cross the p-n junction to be collected. This increases the transport length and time for collection, which in turn increases the resistive losses and the probability of carrier recombination before collection. Lateral transport paths to the top electrode 104, indicated by the curved arrows, also increase the device resistance leading to power loss.

The maximum voltage provided by the device 110 (and PV devices in general) is the open circuit voltage which is determined by the band-gap energy, E_{g}, of the absorbing region 110 and the incident power density, among other things. Under typical operating conditions of a conventional top-illumination device 100 the open circuit voltage is typically 0.2-0.4 V less than the band-gap energy, E_{g} (in eV) of the absorbing region 110, demonstrating significant power loss through loss mechanisms such as those described above.

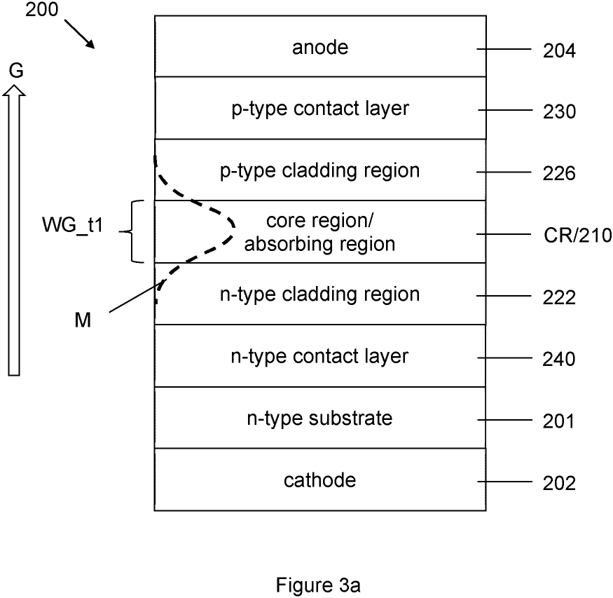

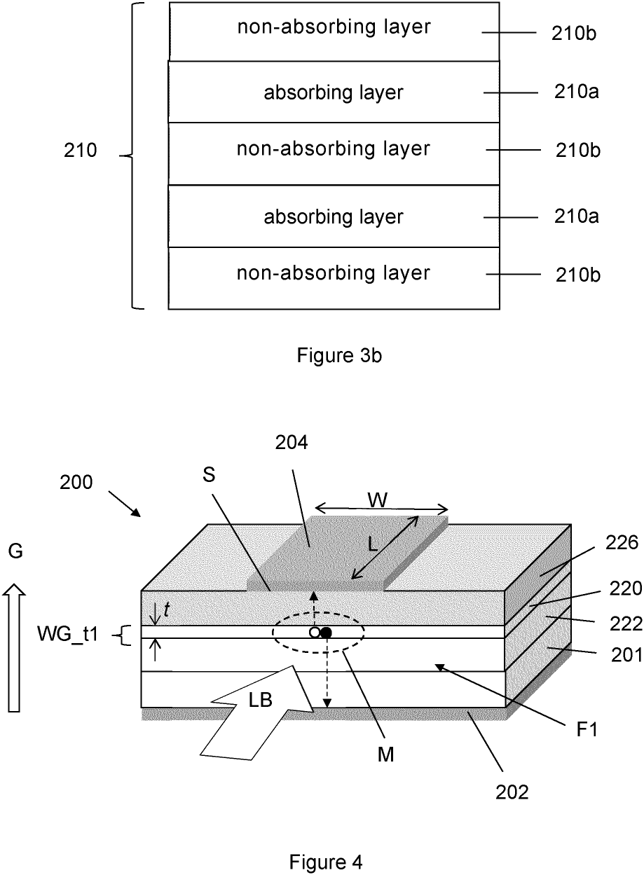

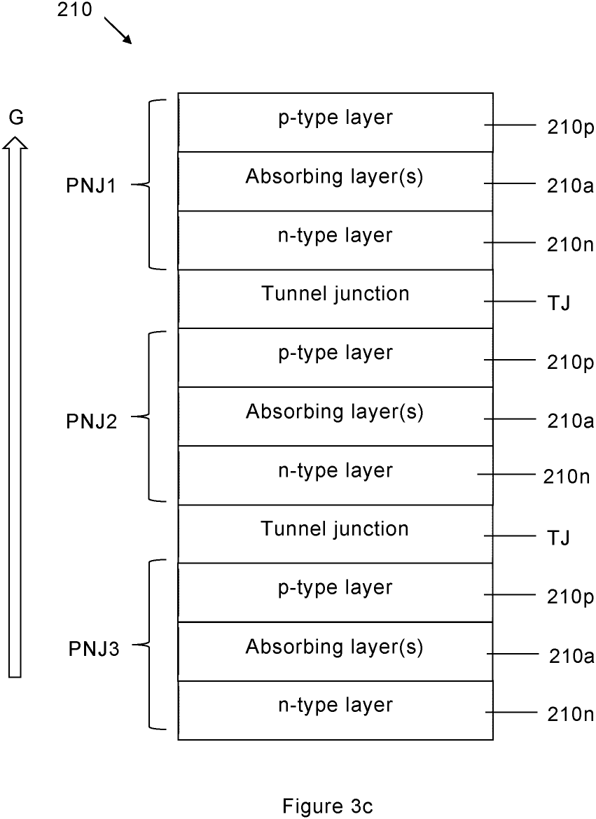

FIGS. 3a, 3b, 3c and 4 show an optical power converter device 200 according to an embodiment of the invention. The device 200 is configured for side illumination and comprises a semiconductor waveguide structure to guide light along the length of the device 200 with a thin absorbing region 210 arranged to absorb the guided light. The waveguide structure comprises a sequence of semiconductors layers to provide the required index contrast and arrangement n-type and p-type regions for separating and extracted photo-generated carriers. The layer structure comprises an n-type substrate 201, an n-type cladding region 222, a p-type cladding region 226, a core region CR positioned between the n-type and p-type cladding regions 222, 226, and an absorbing region 210 within the core region CR (N.B. if a p-type substrate is used, the position of the n and p-type regions is switched). The absorbing region 210 comprises one or more absorbing layers 210a with a band-gap energy E_{g} ≤ Eₚₕ and a total thickness t of less than 100 nm in the growth direction G. The core region CR has a higher refractive index than that of the n-type and p-type cladding regions 222, 226 to form a transverse (slab) waveguide WG_t1 for confining light in the growth direction G to one or more guided modes M (indicated by the dashed line in FIGS. 3a and 4). The n-type and p-type cladding regions 222, 226 and the core region CR (excluding the absorbing layer(s) 210a) have a band-gap energy E_{g} > Eₚₕ so that they are substantially transparent to the incident light beam LB. The n-type and p-type regions 222, 226 form a p-n junction for separating photo-carriers generated in the light absorbing region 210, and are electrically contacted by a low resistance cathode 202 (bottom electrode) and anode 204 (top electrode), respectively, for outputting generated electrical power.

In the illustrated embodiment, the absorbing region 210 is positioned within, or forms at least part of, the higher index core region CR. However, this is not essential. For example, the absorbing region 210 can be located within the lower index n-type or p-type cladding regions 222, 226 (not shown) provided it is within the envelope or spatial extent of a guided mode M (any mode in general, but preferably the fundamental mode) of the waveguide WG_t1 to thereby absorb guided light. The waveguide WG_t1 can be configured to be single mode for the wavelength of incident light, but can be also advantageously multi-moded, depending on the application. Although shown as separate regions in FIGS. 3a and 4, the cladding region adjacent the substrate 201 can include the substrate 201 itself, if the substrate 201 is transparent to the incident light.

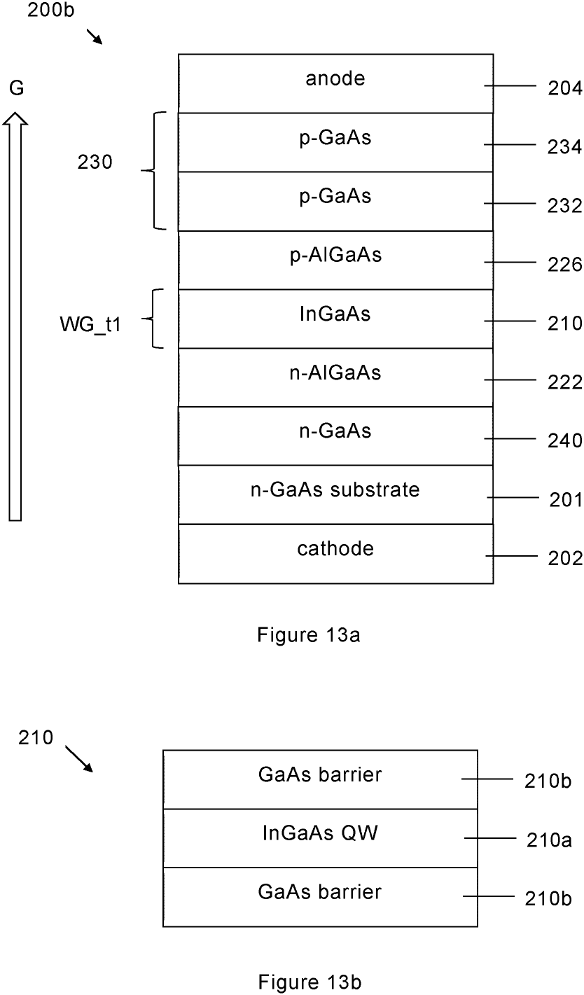

Each region of the device 200 comprises one or more semiconductor layers. In particular, the absorbing region 210 comprises one or more absorbing layers 210a, such as a sequence of absorbing and non-absorbing/transparent layers 210a, 210b, as shown in FIG. 3b. In an embodiment, the one or more absorbing layers 210a are QWs 210a or layers of quantum dots (QDs) 210a, as is known in the art. For example, the device may comprise 1 to 10 QWs 210a sandwiched between non-absorbing/transparent barrier layers 210b (e.g. see FIG. 13b), where the total thickness of the QWs 210a is less than 100 nm.

The n-type and p-type cladding regions 222, 226 are doped to have a charge carrier density/concentration in the range of 0.1-5 ×10¹⁸ cm⁻³ to minimise resistance without introducing excess free carrier loss. The layer structure may also comprise an n-type contact layer 240 and a p-type contact layer 230 between the respective n-type and p-type cladding region 222, 226 and cathode/anode 202, 204 to reduce the contact resistance of the respective cathode and anode 202, 204 and thereby assist power extraction, as is known in the art (see FIG. 3a). The contact layers 230, 240 are more highly doped than the respective cladding regions 222, 226 and/or are formed of a semiconductor material with a lower band-gap energy than that of the respective cladding regions 222, 226. In this embodiment, the absorbing region 210 and the core region CR are un-doped (i.e. intrinsic).

In an embodiment, the absorbing region 210 comprises a series of epitaxially stacked (in the growth direction G) p-n junctions PNJ1-PNJ3, three in this example, each containing at least one of the one or more absorbing layers 210a, e.g. one or more quantum wells and/or layers of quantum dots 210a, as shown in FIG. 3c. Each p-n junction PNJ1-PNJ3 is formed by a p-type semiconductor layer 210p and an n-type semiconductor layer 210n and is separated by a low resistance tunnel junction TJ. In this case, the transverse waveguide WG_t1 forms essentially a single multimode waveguide containing all the p-n junctions PNJ1-PNJ3. Alternatively, the layer structure of the n-type cladding layer 222, absorbing region 210 and the p-type cladding region 226 can be repeated in the growth direction, separated by a low resistance tunnel junction, to form the series of stacked p-n junctions (not shown). In this case, each p-n junction may form a separate transverse waveguide WG_t1 (which can be single mode). Under edge or side illumination, the resultant series connection of p-n junction (i.e. diodes) will result in a summation of the voltage of each of the number of p-n junctions and a reduction in current by the corresponding number. This permits the delivery of higher voltages to the system.

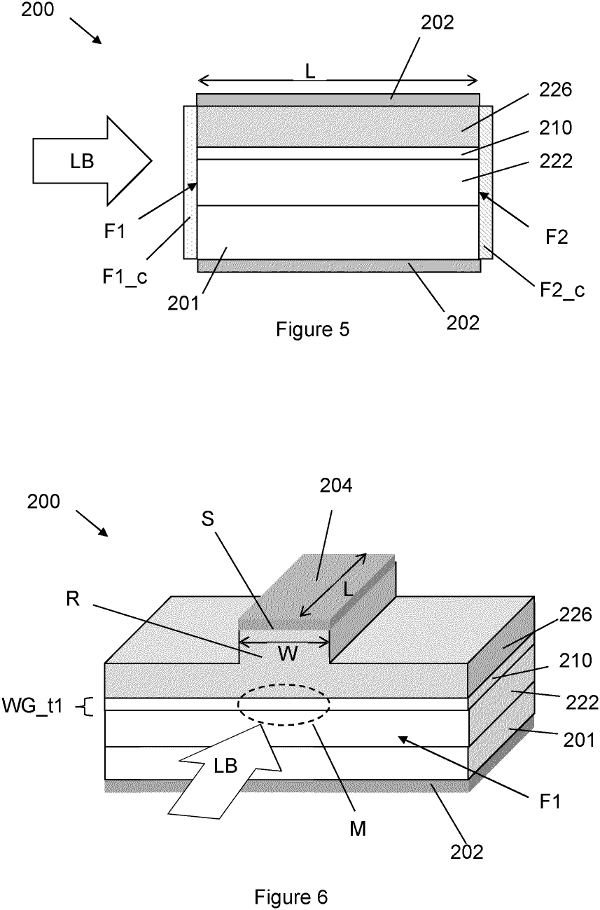

FIG. 5 shows a side view of the device 200. The device 200 comprises a first (front) end facet F1 for receiving a light beam LB in a direction perpendicular to the growth direction G, and a second (rear) end facet F2 substantially opposite the first end facet F2. The distance between front and rear end facets F1, F2 defines the length L of the device 200 and absorbing layer(s) 210a. The anode/top electrode 204 extends along the entire length L of the device 200, as will be discussed in more detail below. The front end facet F1 includes an anti-reflection coating F1_c for the wavelength of incident light to reduce transmission losses by reflection, as is known in the art. For example, the coating F1_c may be a layered dielectric coating configured to reduce the reflectance of the wavelength of incident light to between 0.01 and 10%. The rear end facet F2 can include a highly reflective coating F2_c for the wavelength of incident light to direct/reflect any light not absorbed over the length L of the device 200 back through the device 200 for a second pass. For example, the coating F2_c can be a metal mirror coating, as is known in the art. In this case, the plane of the rear end facet F2 is substantially parallel to the growth direction G and perpendicular to the direction of light propagation in the waveguide structure. The plane of the front end facet F1 can be parallel to the rear end facet F2 as shown, or it can be inclined at an angle between 0 and 8 degrees to the growth direction G to reduce feedback to the light source.

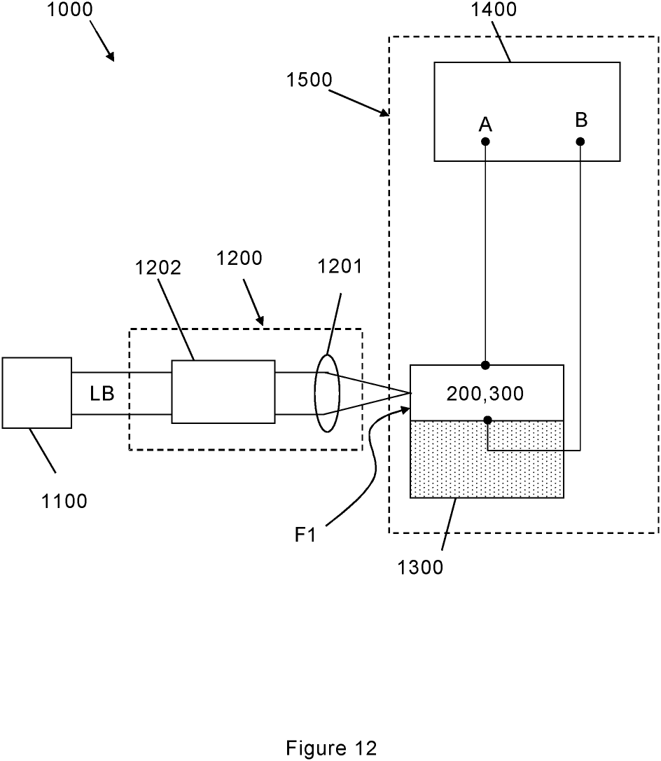

In use, a light beam LB with a photon energy Eₚₕ at or just above the band-gap energy E_{g} of the one or more absorbing layers 210a is incident onto the front end facet F1 in a direction substantially normal to the growth direction G and couples into the transverse waveguide WG_t1. Light is guided by and propagates along the waveguide WG_t1 in one or more modes M, where it is absorbed along the length L of the absorbing layer(s) 210a by virtue of the spatial overlap (Γ) with the mode(s) M. Photo-carriers are generated directly in the absorbing layer(s) 210a and are separated and collected by the n-type and p-type cladding regions 222, 226. This generates a forward bias on the device 200. As the light power is increased, the generated current and voltage increases and the device 200 can be used as an electrical power source, e.g. by connecting an electrical component 1400 to the cathode and anode 202, 204 (see FIG. 12). Light can be efficiently coupled into the waveguide WG_t1 using a number of techniques known in the art. In one example, a lens 1201 is used to focus the light beam LB onto the front end facet F1 within the numerical aperture of the waveguide WG_t1 (see FIG. 12). However, other means known in the art, such as a butt coupling can also be used (not shown). In alternative arrangement (not shown), a grating or prism coupling can be used to allow light to be coupled into the waveguide WG_t1 at an oblique angle of incidence.

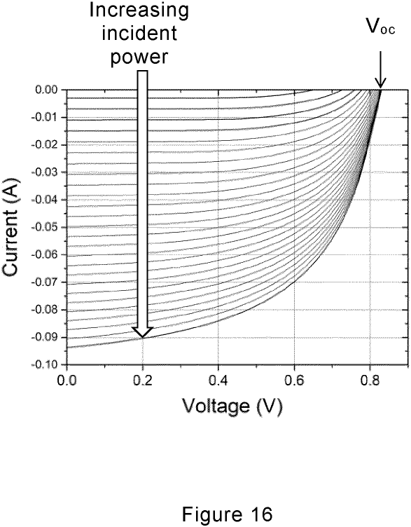

The device 200 solves several problems with the top illumination power converter device 100 described above. Because photo-carriers are generated directly in the thin absorbing layer(s) 210a within the p-n junction, there is a minimal transport distance to reach and be collected by the respective n- and p-type cladding regions 222, 226, which reduces recombination losses. Further, because light is incident from the side of the device 200 there is no shadowing of incident light by the top electrode 204 and photon/transmission losses at the light receiving surface substantially reduced. The top electrode 204 extends along the entire length L of the device with a width W to match the width of the incident light beam LB and/or waveguide mode M facilitating efficient carrier extraction with minimum resistive losses (e.g. see FIG. 4). This top electrode configuration allows a low resistance Ohmic metal top contact 204 to be formed with low contact and spreading resistance, and photo-carriers to be extracted/collected without lateral transport. Example transport paths of photo-generated electrons (solid circle) and holes (open circle) are indicated by the dashed arrow in FIG. 4. In addition, because the absorbing layer(s) 210a is relatively thin (< 100 nm), the photo-carrier density (cm⁻³) is higher than it is for a conventional device 100 with a 2-4 µm thick absorber 110 under the same incident light conditions, which increases the generated power output of the device 200. As a result of these advantages, open-circuit voltages (V_{oc}) within 5 or 10% of the band-gap energy E_{g} of the absorbing layer(s) 210a can be generated by the device 200 (see discussion of FIG. 16).

Absorption of light in the absorbing layer(s) 210a is distributed over the propagation distance x in the waveguide WG_t1 according to the Beer-Lambert law:

$$\text{I} \left(\text{x}\right) = \text{I} \left(0\right) \text{exp} \left(\text{-} Γ α \left(λ\right) \text{x}\right) \qquad \text{(1)}$$

where I(0) is the initial intensity (W/cm²) of light at the first end facet F1, I(x) is the remaining intensity of light after propagating a distance x (where 0 ≤ x ≤ L), Γ is the spatial overlap factor of the waveguide mode M with the absorbing layer(s) 210a (ranging from 0-1), and α(λ) is the absorption coefficient of the semiconductor material of the absorbing layer(s) 210a as a function of the wavelength λ of incident light. The absorption length is defined as the propagation distance L_{α} = 1/Γα(λ)over which the light intensity drops by a factor e = 2.7182.

The operating principle of the device 200 is based upon having low absorption of light in the thin absorbing layer(s) 210a distributed over a long distance. Low absorption is achieved by having a low overlap factor Γ, by reducing the thickness or number of the absorbing layers 210a and/or by the increasing the transverse size of the mode M (e.g. by engineering the materials or thicknesses of core and cladding regions). In an embodiment, the waveguide WG_t1 is configured to provide an overlap factor Γ less than 0.1 (< 10%) and preferably less than 0.01 (< 1 %). As a result, the absorption per unit length of light propagation (Γα(λ)) in the absorbing layer(s) 210a is relatively low compared to a conventional top illumination device 100 where the overlap is almost 100%. However, the total absorption in the device 200 is high, and complete absorption is achievable, because absorption occurs over a long optical path/propagation length x which is at least equal to the device 200 length L, which in turn is substantially greater than the absorption length L_{α}. By way of example, near band-edge wavelength light (Eₚₕ ~ E_{g}) is typically fully absorbed over a distance of about 4 µm in a direct bandgap material such as GaAs with 100% overlap (Γ = 1). This is distance is extended to about 400 µm when Γ = 0.01.

In an embodiment, the length L of the device 200 is greater than 300 µm. In this case, substantially all the incident light is absorbed. Any light not absorbed over the length L of the device 200 is reflected at the rear end facet F2 (e.g. assisted by the reflective coating F2_c) for a second pass of the waveguide WG_t1 which further increases the path length x, as is known in the art (see FIG. 5).

The photo-generated charge density in the absorbing layer(s) 210a is proportional to the light intensity and therefore also decays with distance from the front end facet F1 with a functional form similar to that of equation 1. As such, movement of the photo-generated electrons and holes to the respective cathode and anode 202, 204 generates an initially non-uniform voltage on the device 200. However, this voltage is rapidly re-distributed over the length L and width of the device 200, along with the extracted power (I*V), within the resistance-capacitance (RC) time constant of the device 200 due to the low resistance cathode and anode 202, 204 (particularly the anode/top electrode 204) that provide equipotential surfaces extending along the length L of the device 200.

In the embodiment of FIG. 4, the top contact/anode 204 is provided as a strip having a width W which defines the lateral width of the waveguide mode(s) M. The strip contact 204 modifies the effective refractive index of the transverse/slab waveguide WG_t1 in the region beneath it, which provides lateral confinement (i.e. in a direction perpendicular to the growth direction G and light propagation). The transverse waveguide WG_t1 and the stripe contact 204 together form a channel waveguide that guides light in two-dimensions, as is known in the art

FIG. 6 shows an alternative embodiment of the device 200 where the waveguide structure comprises a ridge or ridge pattern R to provide lateral confinement and assist in lateral guiding of light propagation. The top electrode/anode 202 covers the top surface S of the ridge R. The transverse waveguide WG_t1 and the ridge R together form a channel or ridge waveguide that guides light in two-dimensions, as is known in the art. The ridge can be formed by an etching process during device fabrication, as is known in the art. The depth of the ridge extends at least partly through the p-type (upper) cladding layer 224 as shown, but can extend through the absorbing layer(s) 210 (not shown). In an embodiment, the length of the ridge R is equal to the length L of the device 200 and the width W is in the range 2 to 500 µm.

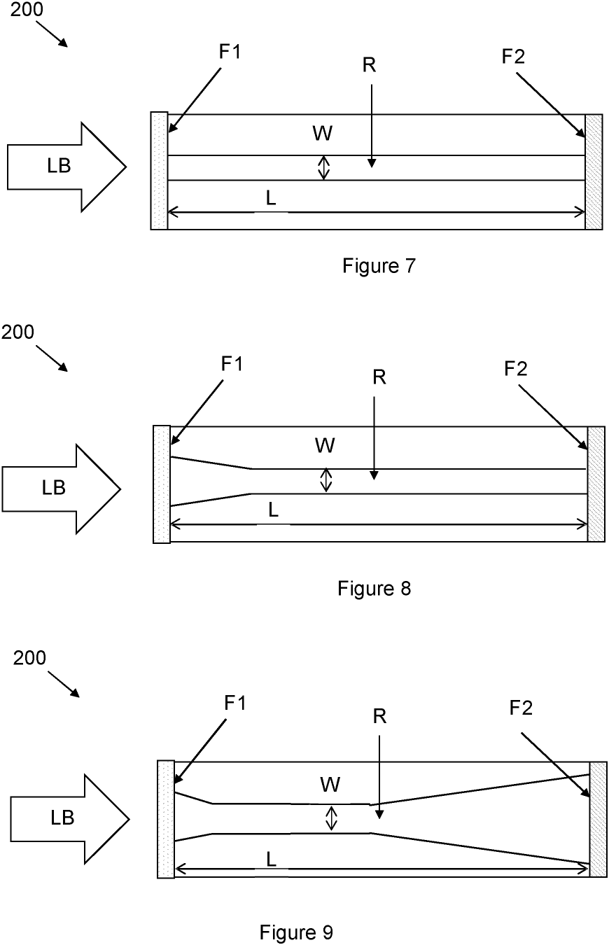

The width W of the top contact 204 and/or ridge R provides control over the width of the waveguide mode M and, together with the device length L, the area (A = L x W) over which light is absorbed in the absorbing layer(s) 210a (see FIGS. 7 to 9). For a given incident optical power (Pᵢ), the spatial overlap Γ, absorption coefficient α, area A and the thickness t of the absorbing layer(s) 210a determine the generated photo-carrier density. Since the device 200 is preferably operated at maximum incident power, the area A can be used to set the operating point of the device 200. The area A can be precisely controlled during device fabrication and configured to achieve an predefined/optimum photo-carrier density at the maximum input power for generating a high power output (as described above) while avoiding non-linear saturation effects. In an embodiment, the optimum photo-carrier density is the transparency density in open circuit conditions, which is approximately 1-2 ×10¹⁸ cm⁻³ for GaAs and indium phosphide (InP)-based semiconductors. The transparency density is the density at and beyond which the absorbing layer(s) 210a stops being absorbing to the incident light. Beyond this point, i.e. at greater incident powers, the optical gain occurs and the device 200 can operate in stimulated emission mode, e.g. as a laser.

By way of example only, consider an incident light beam LB with Pᵢ = 1 W, Eₚₕ = 1 eV, and a spot size of 5 µm² (beam width ~ 2.5 µm), an absorbing region 210 having a single t = 10 nm thick QW 210a where Γ = 0.01 and α = 8,000 cm⁻¹, and a ridge width W = 3 µm. According to equation 1, assuming full transmission through the front end facet F1, 1% of the light remains after a propagation distance x₁ = 570 µm (by equating exp(-Γαx₁) = 0.01). Over this distance, Pᵢ/(Eₚₕ * e * x₁ * W * t) = 0.36 × 10³⁰ cm⁻³s⁻¹ photo-carriers are generated per second per unit volume, where e = 1.6 × 10⁻¹⁹ J. Assuming a carrier lifetime of 5 ns, this leads to a nominal photo-carrier density of ~ 1.5 × 10²¹ cm⁻³ in open circuit conditions. At that photo-carrier density the device 200 would be operating in stimulated emission mode, i.e. not as an efficient optical power converter. To achieve a transparency photo-carrier density of ~ 1.5 × 10¹⁸ cm⁻³ at open circuit, the photo-carrier density must be diluted by a factor of about 1000. This can be done by controlling the thickness t or overlap Γ of the absorbing layer(s) 210a, and/or by increasing the area A = L x W of the waveguide or top contact 204. In practice, the waveguide area A operates as the primary buffer to control the generated photo-carrier density, but this can only work if the generated voltage is re-distributed over the length L and width W of the top electrode 204, as described above.

The thickness t of the transverse waveguide WG_t1 and width W of the top contact/ridge R provides control over the size and shape of the resulting waveguide mode M. In practice, this also determines the required light beam LB profile for efficiently coupling incident light into the waveguide, and incident light beam LB profile can be matched to the waveguide mode M, or vice versa.

FIGS. 7 to 9 show top views of the device 200 of FIG. 6 with ridges R of different shapes. The width W of the ridge R may be substantially constant over its length L as shown in FIG. 7, or it may vary over at least a portion of its width W as shown in FIGS. 8 and 9. In particular, the width W may taper out towards the front end facet and/or the rear end facet F2 (see FIGS. 8 and 9). A front end taper may help to compensate for the increased light absorption in that region by diluting the photo-carrier density. The width W of the strip contact 204 may be varied in the same way, with or without a ridge R (not shown).

At the open circuit voltage of the device 200, no power is extracted through the contacts 202, 204 (generated photo-carriers have nowhere to go) and energy can dissipate through radiative (e.g. spontaneous emission) and non-radiative carrier recombination. Emitted light can be re-cycled using appropriate reflective layers and/or coatings. In an embodiment, the front end facet coating F1_c is also configured to be highly reflective for the emission wavelength where this is different to the incident wavelength, and the rear end facet coating F2_c is configured to be highly reflecting for the wavelengths of both the incident and emitted light. In addition, a distributed Bragg reflector (which may be part of the layer structure) and/or a highly reflective metal-based mirror (which may be part of the bottom electrode 202) can be also included to recycle light emitted towards the bottom electrode 202 (not shown), as is known in art. Defect or trap related non-radiative carrier recombination can be minimised by the use of high crystalline quality semiconductor materials (see below). Auger recombination, a non-radiative recombination process well known in the art, can be limited by keeping the photo-carrier density below a suitable level and by using a material where Auger effects are minimal. For example, Auger recombination is proportional to the carrier density cubed and the strength of the effect depends on the material and wavelength (it is minimal below 1350 nm for indium gallium arsenide (InGaAs)-based materials).

The photo-response of the device 200, and therefore the absorption of the light in absorbing layer(s) 210, should preferably be independent of the polarisation of incident light. Where the absorbing layer(s) 210a is a QW or a QD layer 210a, the absorption is polarisation dependent for near band-edge wavelength light (where Eₚₕ ~ E_{g}), but becomes polarisation independent at higher photon energies Eₚₕ > E_{g}. In such cases the photon energy Eₚₕ can be offset above the band edge E_{g}. The offset should be sufficient for absorption to be polarisation independent while minimising thermalization losses. In an embodiment, the offset is between 50 and 100 meV above the band edge E_{g}.

At high enough incident powers, where the photocarrier density and current density exceed a threshold (such as the transparency density of about 1-2 × 10¹⁸ cm⁻³), stimulated emission occurs and the device 200 can operate as an optically pumped laser. In practice, the device 200 may switch from an efficient absorber to a laser quite abruptly, once some additional losses are overcome. In an embodiment, the device 200 is operated in the stimulated emission mode while current is extracted and emitted light from the device 200 is modulated to transmit information back towards the source. The emitted light can be modulated by applying a bias to the cathode and anode. Since the emitted wavelength of the optically pumped device 200 is down-converted from the pump/incident wavelength (e.g. since Eₚₕ > E_{g}), the emitted light (i.e. optical output signal) can be separated from the pump/incident light at the source/receiving end. For example, the device 200 can be used to power a separate electronic component or device, and that device may be configured to generate a modulated data output (voltage) signal that can be applied to the anode and cathode to modulate the emitted light. This allows both remotely powering and communicating of remote devices. In such applications, the optical power converter device 200 can both convert the incident (pump) light beam to power a remote device/electronic component and generate an optical signal (through light emission) to send information back from it. This has advantages in confined spaces, one such application being at the distal end of an endoscope where a camera could be located and powered by the optical power converter device 200. This provides a significant advantage in compactness as a single fibre and a single device can provide the channel for both the powering and the signalling. Operating in this mode is less efficient (compared when the device 200 is not emitting) due to sacrificing the energy needed to make the device 200 lase, but has the significant advantage that the same device (and coupling) can be used to power and signal.

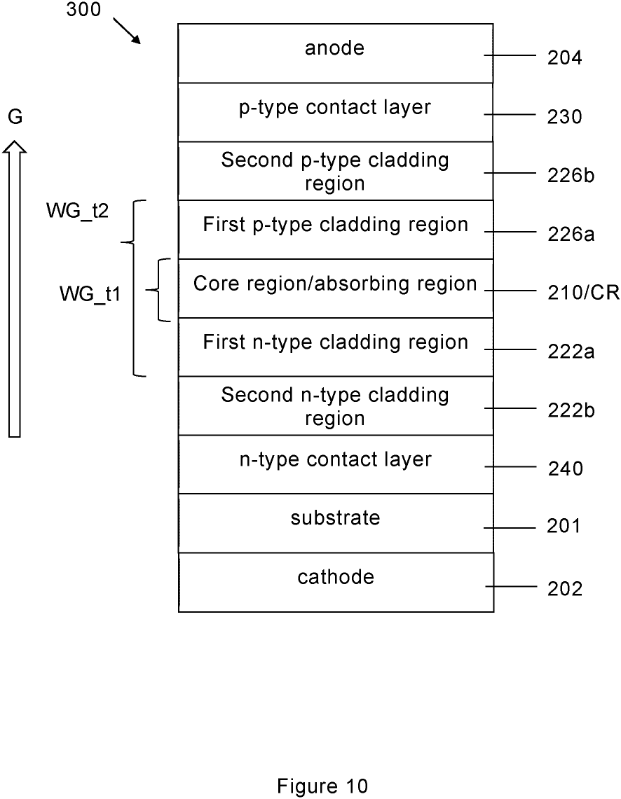

FIG. 10 shows another embodiment of an optical power converter device 300 according to the invention. The device 300 has the same features as device 200 but the waveguide structure is configured as a double clad waveguide structure with an inner waveguide WG_t1 and an outer waveguide WG_t2. The n-type cladding region 222 includes a first (inner) n-type cladding layer 222a and a second (outer) n-type cladding layer 222b, and the p-type cladding region 226 includes a first (inner) p-type cladding layer 226a and a second (outer) p-type cladding layer 226b, with respect to the core region CR. The outer cladding layers 222b, 226b have a refractive index that is lower than that of the inner cladding regions 222a, 226a so as to provide an outer transverse waveguide WG_t2 (which is typically multi-mode) for confining light to a region including the first n-type and p-type cladding layers 222a, 226a, core region CR and absorbing region 210.

The double clad waveguide structure allows a light beam LB with greater width (e.g. greater than 10 µm wide) to couple into the device 300 to deliver more light for converting to electrical power. In use, incident light in a wider light beam LB couples first to the outer waveguide WG_t2, and then to the inner waveguide WG_t1 as it propagates, where it can be efficiently absorbed by the light absorbing layer(s) 210a.

The principle of the double clad waveguide structure is the following. The power density (in terms of W/cm²) of the light beam LB incident on the front end facet F1 must be kept below the damage threshold value, which is typically around 10 MW/cm² for most semiconductor materials. To efficiently couple to a waveguide, the size/beam width of the incident light beam LB at the front end facet F1 should be substantially matched to the size of the waveguide mode M. Thus, the power density at the front end facet F1 for a given maximum incident power is primarily set by the size of the waveguide mode M. Increasing the thickness of the core region CR increases the size of the waveguide mode M and allows wider light beams LB to be used. For a fixed power this reduces the incident power density. Wider light beams LB also increase/relax the alignment tolerances for coupling the incident light beam LB to the waveguide. However, in a single clad waveguide structure as in device 200, increasing the thickness of the core region CR would further reduce the overlap Γ of the collected light with the absorbing layer(s) 210 requiring potentially impractically long device lengths L to achieve total light absorption. The double clad waveguide structure of device 300 allows light to be coupled into the inner waveguide WG_t1 (containing the absorbing layer(s) 210a) using a wider light beam LB than would be possible in an equivalent single clad waveguide structure, and without changing the mode size of the inner waveguide WG_t1. By using a wider light beam LB, more optical power can be delivered to the device 300 at a given power density, or the same optical power can be delivered to the device 300 at a lower power density.

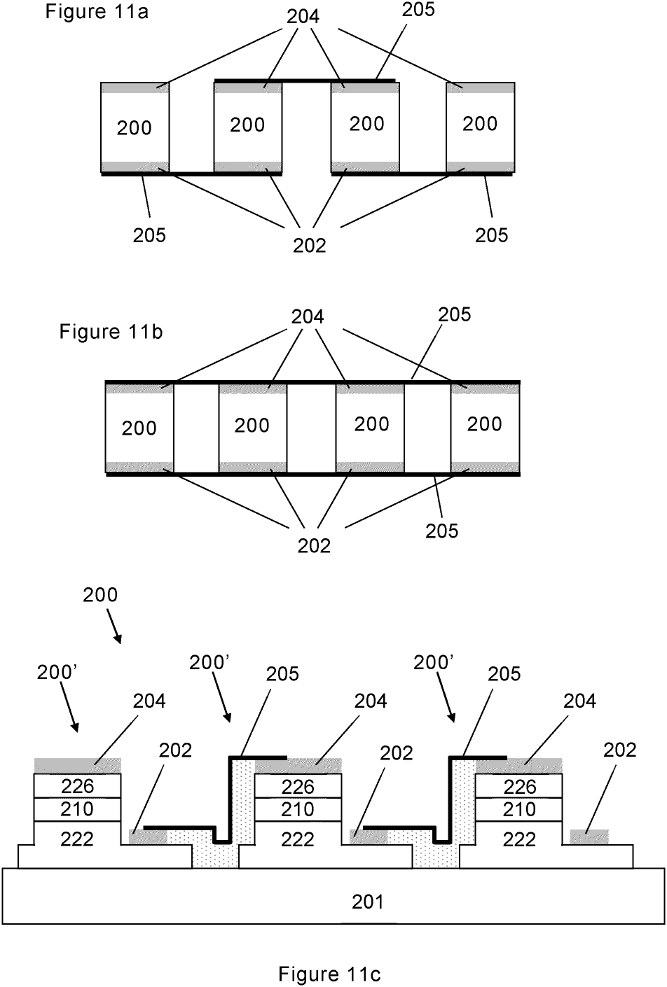

FIGS. 11a and 11b show multiple devices 200, 300 connected in series and parallel to increase the voltage or current output, receptively. To form a series connection, the cathode 202 of a first device 200, 300 is electrically connected to the anode 204 of the next device 200, and so on, by interconnects 205. To form a parallel connection, the cathode 202 of each device 200, 300 is electrically connected by an interconnect 205 and the anode 204 of each device 200, 300 is electrically connected by an interconnect 205. In this case, the front end facet F1 of each device 200, 300 is arranged to receive a separate light beam LB (not shown), which may come from the same source or different sources, and the generated voltages or currents in each device 200, 300 add depending on the configuration.

FIG. 11c shows an embodiment of the device 200 comprising an array of sub-devices 200′ electrically connected in series (the same principle can be applied to device 300). In this case, the semiconductor layer structure is grown on a semi-insulating or substantially non-conducting substrate 201, and the array of sub-devices 200′ are formed from the semiconductor layer structure provided on the substrate 201 using standard semiconductor fabrication techniques, such as lithography, etching, deposition and ion implantation. Each sub-device 200′ has a respective cathode and anode 202, 204. Similar to the arrangement in FIG. 11a, the cathode 202 of a first sub-device 200′ in the array is electrically connected to the anode 204 of the next sub-device 200′ and so on by interconnects 205 to form a series connection, as shown. The front end facet F1 of each sub-device 200′ is arranged to receive a separate light beam LB (not shown), which may come from the same source or different sources, and the generated voltages in each sub-device 200′ adds up. Although the illustrated embodiment shows a series connection, it will be appreciated that a similar arrangement of sub-devices 200′ can be implemented for a parallel connection.

FIG. 12 shows a power-by-light system 1000 comprising an optical power converter device 200, 300 according to an embodiment. The system 1000 comprises a coupling arrangement 1200 for directing the incident light beam LB to the first end facet F1 of the device 200, 300 in a direction substantially perpendicular to the growth direction G. The coupling arrangement 1200 comprises a lens 1201 for receiving an incident light beam LB and coupling the light beam LB to the waveguide structure. This can be achieved by aligning the focused light beam LB within the numerical aperture of the waveguide WG_t1, WG_t2, as is known in the art. The coupling arrangement 1200 also comprises an optical fiber 1202 for guiding the light beam LB from a light source 1100, in this case a laser, to the lens 1201. Alternatively, light emitted from the source 1100 can be delivered to the lens 1201 through free-space. The laser 1100 emits monochromatic or narrow spectral bandwidth light at photon energy Eₚₕ at or just above the band-gap energy E_{g} of the absorbing region 210, as described above. The cathode and anode 202, 204 of the device 200, 300 are connected/connectable to power terminals A and B of an electrical component or system 1400 for providing converted electrical power to the electrical component or system 1400. Multiple devices 200, 300 or multiple sub-devices 200′, 300′ can be used as described above. In that case, a separate lens 1201 is used for each device 200, 300 or sub-device 200′, e.g. a fiber array and a lens array (lens-ended fiber array) can be used. In an embodiment, the device 200, 300 and the electrical component or system 1400 are provided or fabricated on the same semiconductor chip 1500.

The system 1000 further comprises a passive cooling arrangement 1300 for removing heat generated from unconverted optical energy from the device 200, 300. The cooling arrangement 1300 comprises a heat sink in thermal contact with the device 200, 300. The heat sink comprises a material with high thermal conductivity, such as copper or ceramic or any other suitable heat sink material known in the art. The heat sink may be coupled directly or indirectly to either the cathode or anode 202, 204. Where the device 200, 300 and the electrical component or system 1400 are provided or fabricated on the same semiconductor chip 1500, the heat sink may be shared between them.

For optical power transfer by fibers, wavelengths in the range 1300 - 1600 nm are most suitable for delivering optical power over long distances with low attenuation inside the fiber(s). It is also desirable to operate in the 800 - 1300 nm range to take advantage of high power glass and fibre lasers for optical power delivery. Operation of the optical power converter device 200, 300 with different incident wavelengths is achieved through the choice of the semiconductor materials making up the waveguide structure. In particular, by choosing a semiconductor material for the absorbing layer(s) 210 with a band-gap energy E_{g} matched to the incident photon energy Eₚₕ as described above.

The semiconductor layers of the device 200, 300 are formed of direct band-gap III-V compound semiconductor materials. III-V semiconductor layers with direct band-gaps in the range of 300 nm to 4000 nm can be epitaxially grown with high crystal quality using known methods such as molecular beam epitaxy (MBE) and metal organic vapour phase epitaxy (MOVPE). GaAs-based materials can be used for efficiently converting light in the 600 nm to 1300 nm wavelength range. Gallium nitride (GaN)-based materials can be used for converting light in the 360 nm to 500 nm range. InP-based materials can be used for converting light in the 1100 nm to 2000 nm range. Gallium antimonide (GaSb)-based materials can be used for converting light in the 1500 nm to 3000 nm wavelength range.

A particular application of the waveguide power converter device 200, 300 is in powering photonic integrated circuits, e.g. comprising silicon or SiN waveguides. Such circuits have widespread application in data centres, consumer products and in the Internet of Things. The circuits are connected via optical fiber to send and receive information (i.e. optical data signals). The same or an additional optical fiber can be used to deliver optical power to the photonic integrated circuit thereby saving the connection of an external electrical connection. Therefore, in an embodiment, a photonic integrated circuit comprises a power converter device 200, 300 for powering the circuit. In one example, the power-by-light system 1000 comprises a photonic integrated circuit (which can take the place of, or be part of, the semiconductor chip 1500) with a power converter device 200, 300 for powering the circuit. Where the same fiber is used to transmit the optical signal and power, the light delivered through the fiber can be at a separate wavelength to the operation of the signal channel of the photonic integrated circuit, and the power providing wavelength can be separated on the photonic integrated circuit and delivered to a waveguide power converter 200, 300, as described above. Alternatively, a separate fiber containing the powering wavelength can be provided. The light can be delivered to the photonic integrated circuit by grating couplers, butt coupling, or other techniques known in the art. The waveguide power converter device 200, 300 can be integrated on the photonic circuit using wafer bonding, transfer printing or flip chip methods, as are known in the art.

Specific example embodiments of the devices 200, 300 that operate in the common fiber wavelength ranges are described below.

### Example 1

FIG. 13a shows a first example 200a of the single clad device 200 described above with an absorbing region 210 having an absorption band edge in the range 850 nm to 1300 nm. A layered structure is formed on an n-type GaAs substrate by an epitaxial growth technique, such as MOVPE. In growth order, the layer structure comprises an n-side contact layer 240 formed of n-type GaAs, a lower n-type cladding layer 222 formed of n-type AlₓGa₁₋ₓAs (0<x<1), an InₓGa₁₋ₓAs-based absorbing region 210, an upper cladding p-type cladding layer 226 formed of p-type AlₓGa₁₋ₓAs, a first p-side contact layer formed of p-type GaAs, and a second p-side contact layer 234 formed of heavily doped p-type GaAs. The InₓGa₁₋ₓAs-based absorbing region 210 comprises one or more (between 1 and 10) InₓGa_{1- x}As QWs 210a disposed between GaAs barrier layers 210b, as shown in FIG. 13b.

A low resistance metal anode 204 is provided on the highly doped p-type GaAs contact layer 234 and a low resistance metal cathode 202 is provided on the n-type GaAs substrate to make electrode connections thereto. Suitable materials and fabrication techniques for making low resistance contacts to a given semiconductor material are known in the art. For example, the anode 204 may comprise Ti, Pt, and Au, and the cathode 202 may comprise Au, Ge, and Ni. The cathode and anode 202, 204 can be annealed to improve the electrical contact. The resistance of the cathode and anode 202, 204 can be further reduced by electroplating a thick metal layer such as Au. A lateral waveguide is formed by etching a ridge with a width W in the range 2 to 500 µm. Devices 200a are formed by cleaving the layer structure perpendicular to the lateral waveguide axis to a length L between 300 µm and 3 cm. The resistance of the device 200a is less than 5 Ω and preferably less than 1 mΩ for best performance (low resistive power dissipation) and operation at high incident power e.g. > 1 W (e.g. the device resistance is inversely proportional to the contact area). The front end facet F1 is coated with a layered dielectric coating F1_c configured to reduce the reflectance of the wavelength of incident light to less than 10%, as is known the art. For example, the layered dielectric can be a quarter wave thick layer of dielectric, such as SiN or SiO₂, such that reflections from the surface(s) of the dielectric layer(s) undergo destructive interference for the incident light. Optionally, the coating F1_c can also be configured to be reflecting for the down-converted wavelength of any light emitted from the QW(s) 210a, as is known the art. For example, the layered dielectric can be designed such that reflections from the surfaces undergo constructive interference for the emitted light. The dielectric layers also serve to protect the front end facet F1 from damage at high incident power densities. The rear end facet F2 is coated with a high reflection coating F2_c for the wavelengths of incident and emitted light. Suitable coating materials and fabrication techniques are known in the art. For example, a quarter wave layer of dielectric (e.g. SiO₂) and metal (e.g. Au), or a quarter wave stack comprising several (e.g. 5) alternating layers of low and high refractive index dielectrics (e.g. SiO₂/TiO₂).

The composition (x) and thickness of the InₓGa₁₋ₓAs QW(s) 210a and the AlₓGa₁₋ₓAs cladding layers 222, 226 can be controlled/configured to exhibit the required absorption band edge (effective band-gap energy) and provide a transverse waveguide WG_t1 for incident wavelengths in the range 850 nm to 1300 nm. Auger non-radiative recombination is reduced in this wavelength range and radiative quantum efficiency can be greater than 90% (typically, a good power converter should also be a good light emitter). The QW(s) 210a may be pseudomorphically strained to take advantage of a reduced density of states at the band edge. The barrier layers 210b may be tensile strained to balance the excess strain. In one example, for an incident wavelength of 920 nm, the InₓGa₁₋ₓAs QW(s) 210a can be a 10 nm thick In(17%)Ga(83%)As QW surrounded by GaAs barriers 210b, and the composition of the AlₓGa₁₋ₓAs cladding layers 222, 226 can be graded from 10% to 25% in the direction away from the QW 210a. The doping of the AlₓGa₁₋ₓAs cladding layers 222, 226 can also be graded.

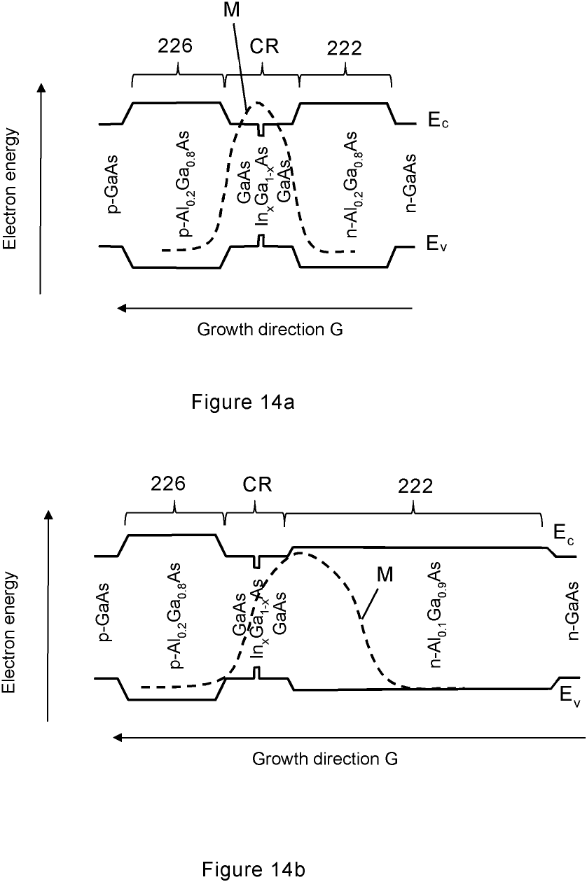

FIG. 14a shows a schematic energy band diagram of the device 200a (under flat band conditions) illustrating conduction band E_{c} and valance band Eᵥ alignment and relative band-gap energies (where E_{g} = E_{c} - Eᵥ) of the layers. The composition (x) of the upper and lower cladding layers 222, 226 is varied/graded at the heterointerfaces to provide a gradual change in the band-gap energy E_{g}, as shown. This may assist photo-carrier extraction (at forward bias). In FIG. 14a, the thickness (in the growth direction G) and composition (x = 0.2) of the upper and lower AlₓGa₁₋ₓAs cladding layers 222, 226 is the same, resulting in a substantially symmetric profile for the fundamental waveguide mode M of the first transverse waveguide WG_t1, as indicated by the dashed curve. FIG. 14b shows an energy band diagram for an alternative configuration where the thickness and composition of the upper and lower AlₓGa₁₋ₓAs cladding layers 222, 226 is different. Here, the lower cladding layer 222 has a lower Al composition (x = 0.1) compared to the upper cladding layer 226 (x=0.2) and is thicker than the upper cladding layer 226, which shifts and broadens the waveguide mode M compared to that in FIG. 14a. This demonstrates that, for a given core region CR, the relative thickness and composition the upper and lower AlₓGa₁₋ₓAs cladding layers 222, 226 can be configured to vary the overlap of the transverse waveguide mode M with the QW(s) 210a. The overlap Γ is in the range between 0.1% and 10% dependent on the layer structure.

### Example 2

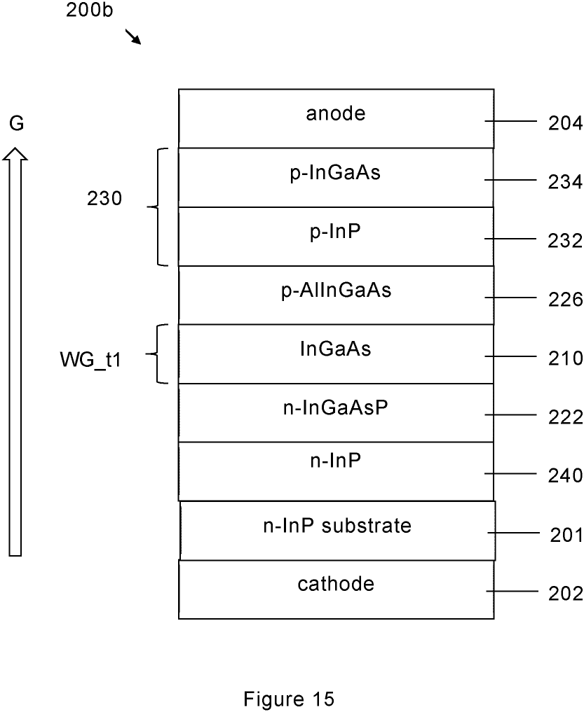

FIG. 15 shows a second example 200b of the single clad device 200 described above with an absorbing region 210 having an absorption band edge close to 1540 nm. The features of the first example device 200a apply equally to the second example device 200b apart from the materials of the layers, as described below. A layered structure is formed on an n-type InP substrate by an epitaxial growth technique, such as MOVPE. In growth order, the layer structure comprises an n-side contact layer 242 formed of n-type InP, a lower n-type cladding layer 222 formed of n-type In₁₋ₓGaₓAs_{1-y}P_{y}, an InₓGa₁₋ₓAs-based absorbing region 210, an upper p-type cladding layer 226 formed of p-type AlₓIn_{1-x- y}Ga_{y}As, a first p-side contact layer formed of p-type InP, and a second p-side contact layer 234 formed of p-type InₓGa₁₋ₓAs. The InₓGa₁₋ₓAs-based absorbing region 210 comprises one or more (between 1 and 10) un-doped InₓGa₁₋ₓAs QWs 210a disposed between AlₓIn_{1-x-y}Ga_{y}As barrier layers 210b, similar that shown in FIG. 13b. The p-type AlₓIn_{1-x-y}Ga_{y}As provides a lower valance band offset for holes than p-type In_{1-xG}aₓAs_{1-y}P_{y}, while n-type In_{1-xG}aₓAs_{1-y}P_{y} provides a lower conduction band offset for electrons than n-type AlₓIn_{1-x-y}Ga_{y}As. In an alternative embodiment, both the upper and lower cladding layers 222, 226 are formed of AlₓIn_{1-x-y}Ga_{y}As or In₁₋ₓGaₓAs_{1-y}P_{y.} A low resistance metal anode 204 is provided on the p-type InGaAs contact layer 234 and a low resistance metal cathode 202 is provided on the n-type InP substrate 201 to make electrical connections thereto, as described above for device 200a.

The composition and thickness of the QW(s) 210a and cladding layers 222, 226 can be controlled/configured to exhibit the required absorption band edge (effective band-gap energy) and transverse waveguide WG_t1 for incident wavelengths in the range of substantially between 1000 nm to 2000 nm. The composition of the upper and lower cladding layers 222, 226 can be graded at their heterointerfaces to assist in carrier extraction as described above with reference to FIGS. 14a and 14b. In one example, the absorbing region 210 comprises a series of five 6 nm thick compressively strained In(0.55)Ga(0.45)As QWs 210a with 10 nm thick Al(0.175)In(0.529)Ga(0.295)As barrier layers 210b to provide a bandgap wavelength of 1547 nm for TE polarized light and 1517 nm for TM polarized light. The waveguide is interfaced on the n-side to n-type InP 240 with a doping of 1×10¹⁸ cm⁻³ and on the p-side to a 20 nm thick AlInAs layer 232 and InGaAsP graded layer 234 (from a 1100 nm to 950 nm band edge energy) doped at 8×10¹⁷ cm⁻³.

FIG. 16 shows current-voltage measurements of an example device 200b with an absorption band edge of approximately 1540 nm obtained under illumination by an incident laser beam emitting at a wavelength of 1430 nm with varying incident powers. The device 200b has a 3 µm wide ridge R and a length L of 1.1 mm. The incident power was increased from 0 to 80 mW in steps of 3.08 mW, and the resistance of the device 200b was 1.6 Ohms. It should be noted that a power of 80 mW corresponds to an estimated incident power density of 2×10⁶ W/cm² which, if absorbed across the entire length of the waveguide structure, would correspond to a current density of approximately 2.7 kA/cm² (80 mA/( 3 µm x 1.1 mm)). Such current densities are orders of magnitude larger than applicable in current laser power converters or in concentrator solar cells. The photon energy Eₚₕ is approximately 60 meV above the band-gap energy E_{g} of the InGaAs QW(s) 210a. Light from a laser source 1100 was delivered onto the anti-reflection coated front end facet F1 by an optical fiber 1202, and a lens 1201 was used to illuminate the ridge waveguide region R with high coupling efficiency by alignment. The incident laser light is naturally polarized. The absorption response of the QW 210a is polarisation dependent near the absorption band edge, but the energy offset of Eₚₕ-E_{g} ≈ 60 meV results in a polarisation independent response of the device 200b. As shown, an open circuit voltage of V_{oc} ≈ 0.83 V is obtained at the maximum input power, which exceeds the band-gap energy E_{g} ≈ 0.805 eV of the InGaAs QW 210a, and an open circuit voltage of V_{oc} ≈ 0.8 V is obtained at relatively low input powers, which is within 5% of the band-gap energy E_{g}. This is due to the high carrier densities achieved as a result of the incident power being absorbed in a few (1-5) QWs 210a. The threshold photocarrier density for lasing in QWs at this wavelength is approximately 2×10¹⁸ cm⁻³, and is reached under the maximum incident power conditions in these this experiment. If we assume an absorption coefficient for the quantum wells 210a of α = 4,000 cm⁻¹ at the incident wavelength and a mode overlap factor Γ of 3%, an absorption length of L_{α} ≈ 80 µm can be estimated, which is much shorter than the total length L of the waveguide (1.1 mm). Even at a Γ of 1%, corresponding to a single QW 210a, the absorption length is L_{α} ≈ 250 µm. As discussed above, the absorption of photons generates a local photovoltage which is then re-distributed along the length of the waveguide through the low resistance metal contacts, resulting in a redistribution of the photocarriers along the entire length of the device 200b within the R-C time constant of the device 200b. This demonstrates that improved performance can be achieved by reducing the mode overlap to < 1 % (by reducing the thickness/number of QWs 210a and/or by increasing the transverse mode size) and increasing the width W and/or length L of the waveguide, which in turn reduces the device resistance and saturation effects. The device 200b is preferably operated at the maximum power point, which is this specific example device 200b is approximately 42 mW (current x voltage) at 0.6 V. The maximum internal conversion efficiency is estimated to be approximately 57 % at an absorbed power of 20 mW.

The operating current density of the device 200b is between 100 - 3000 A/cm². At each forward bias the QW 210a has a certain photo-carrier density which results in radiative recombination. Generated light is recycled by re-absorption, assisted by the waveguide WG_t1 and by reflective structures on the device 200b as described above. If the current density becomes very high (e.g. > 3000 A/cm²) the device 200b can start operating as a laser in stimulated emission mode and generate a voltage greater than the band-gap energy E_{g} due to the splitting of the quasi-Fermi levels. This mode of operation is not optimal as an efficient power converter, but is preferred if a voltage reference is sought.

### Example 3

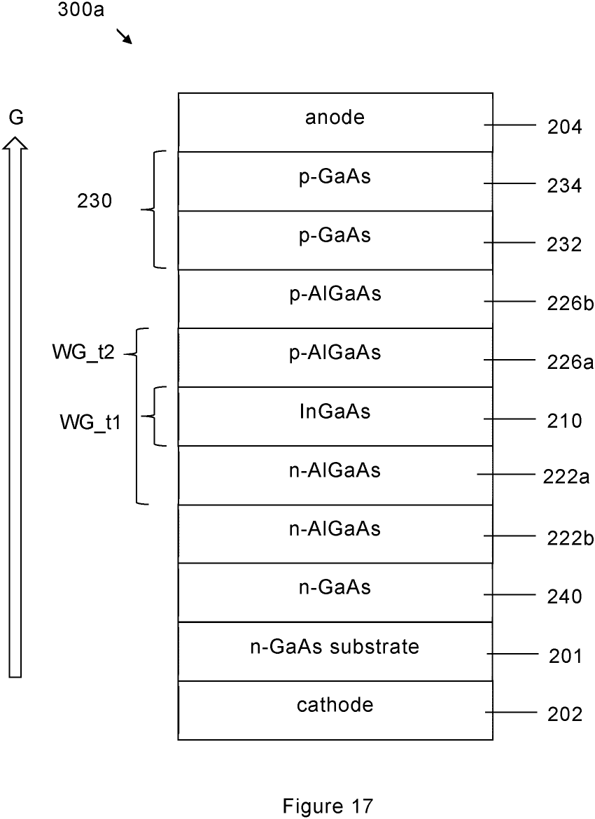

FIG. 17 shows an example 300a of the double clad device 300 described above with an absorbing region 210 having an absorption band edge in the range 850 nm to 1300 nm, by adjusting the composition of the InₓGa₁₋ₓAs quantum well(s) 210a. The device 300a has the same features as device 200a described above, but with an additional n-type cladding layer 222b and p-type cladding layer 226b. In growth order, the layer structure comprises a n-type GaAs substrate 201, an n-side contact layer 240 formed of n-type GaAs, an outer n-type cladding layer 222b formed of n-type AlₓGa₁₋ₓAs, an inner n-type cladding layer 222a formed of n-type AlₓGa₁₋ₓAs with a lower Al composition (x) (i.e. higher index) than cladding layer 222b, an InₓGa₁₋ₓAs-based absorbing region 210, an inner p-type cladding layer 226a formed of p-type AlₓGa₁₋ₓAs, an outer p-type cladding layer 226b formed of p-type AlₓGa₁₋ₓAs with a higher Al composition (x) (i.e. lower index) than cladding layer 226a, a first p-side contact layer 232 formed of p-type GaAs, and a second p-side contact layer 234 formed of heavily doped p-type GaAs. The InₓGa₁₋ₓAs-based absorbing layer 210 comprises one or more (between 1 and 10) un-doped InₓGa₁₋ₓAs QWs 210a disposed between GaAs barrier layers 210b, as shown in FIG. 13b. The second (outer) lower n-type AlₓGa₁₋ₓAs cladding layer 224 has a thickness in the range 5 to 15 µm.

The composition and thickness of the QW(s) 210a and cladding layers 222a, 222b, 226a, 226b and can be selected/configured to exhibit the required absorption band edge (effective band-gap energy) and transverse waveguide WG_t1 for incident wavelengths in the range 850 nm to 1300 nm. In one example, a 20 nm thick GaAs QW 210a will absorb light at 850 nm while a 6 nm thick In_{0.5}Ga_{0.5}As QW will absorb wavelengths up to 1211 nm. The addition of nitrogen to the OW 210a will further extend the wavelength. The use of InP-based structures also enables operation in the 1200 nm to 1650 nm wavelength range.

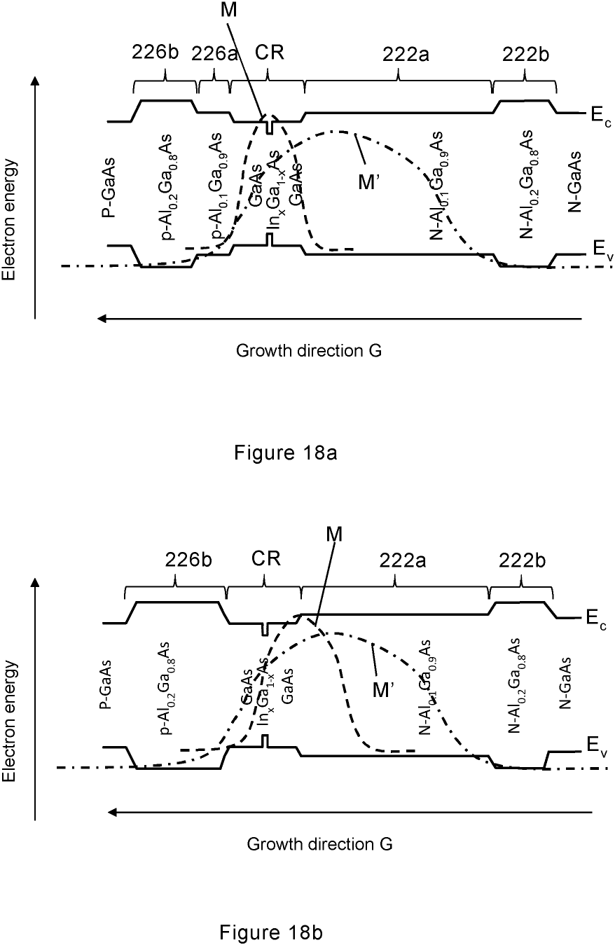

FIG. 18a shows a schematic energy band diagram of the device 300a (ignoring band bending from doping) illustrating conduction band E_{c} and valance band Eᵥ alignment and relative band-gap energies (E_{g} = E_{c} - Eᵥ) of the layers. The composition (x) of the inner cladding layers 222a, 226a is the same (x = 0.1 in this example), and the composition (x) of the outer cladding layers 222b, 226b is the same (x = 0.2 in this example). The composition (x) of the cladding layers 222a, 222b, 226a, 226b is varied/graded at the heterointerfaces to provide a gradual change in the band-gap energy E_{g}, as described for 200a. The profile for the fundamental waveguide mode M of the first transverse waveguide WG_t1 is indicated by the dashed curve. The profile of the fundamental waveguide mode M′ of the second transverse waveguide WG_t2 is indicated by the dot-dashed curve. Note that due to the larger width/thickness of the waveguide WG_t2 (in the growth direction G), it is multi-modal. FIG. 18b shows an energy band diagram for an alternative configuration of the layer structure of the device 300a where the AlₓGa₁₋ₓAs cladding layer 226a is omitted and the AlₓGa₁₋ₓAs cladding layer 226b provides the upper confinement for both the inner and outer transverse waveguides WG_t1, WG_t2. Equivalently, FIG. 18b represents the case where only one of the n-type and p-type cladding regions 222, 226 includes an inner and outer cladding layer.

It will be appreciated that the design principles in example 3 can be applied to an InP-based layer structure as in example 2, or a GaSb-based structure or a GaN-based structure (not shown).

From reading the present disclosure, other variations and modifications will be apparent to the skilled person that are within the scope of the claims. Such variations and modifications may involve equivalent and other features which are already known in the art, and which may be used instead of, or in addition to, features already described herein.

Although the appended claims are directed to particular combinations of features, it should be understood that the scope of the disclosure of the present invention also includes any novel feature or any novel combination of features disclosed herein either explicitly or implicitly or any generalisation thereof, whether or not it relates to the same invention as presently claimed in any claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable sub-combination.

1. An optical power converter device comprising:
a semiconductor waveguide structure having a first end facet configured to receive an incident light beam, and one or more light absorbing layers with a total thickness of substantially less than 100 nm and configured to absorb light guided by the waveguide structure; and
a cathode and an anode in contact with substantially the entire length of the waveguide structure in the direction of propagation of light from the first end facet for outputting generated electrical power,
wherein the optical power converter device operates in a photovoltaic mode such that a positive voltage is generated between the anode and cathode in use.

2. The device of claim 1, wherein the waveguide structure comprises an n-type cladding region, a p-type cladding region, and a core region between the n-type and p-type cladding regions for confining and guiding light; and wherein the cathode and anode are electrically connected to the respective n-type and p-type cladding regions of the waveguide structure.

3-5. (canceled)

6. The device of claim 1, wherein the device is configured to generate an open circuit voltage of at least 90% of the band-gap energy/voltage of the absorbing layer(s).

7. The device of claim 1, wherein the one or more light absorbing layers spatially overlap a guided mode of the waveguide structure.

8. (canceled)

9. The device of claim 1, wherein the n-type and p-type cladding regions are formed of or comprise one or more semiconductor layers having a band-gap energy substantially higher than that of the core region, the one or more light absorbing layers and the photon energy of the incident light beam.

10. The device of claim 1, wherein the waveguide structure is or comprises a double clad waveguide structure.

11. The device of claim 1, wherein at least one of the n-type and p-type cladding regions comprises an inner and an outer cladding layer, with respect to the core region.

12. The device of claim 1, wherein the outer cladding layer(s) is (are) formed of or comprises a semiconductor material with a band-gap energy substantially higher than that of the respective inner cladding layer(s) and the photon energy of the incident light beam.

13. The device of claim 1, wherein the waveguide structure comprises a series of epitaxially stacked p-n junctions, each p-n junction containing at least one of the one or more light absorbing layers.

14-16. (canceled)

17. The device of claim 1, wherein one of the cathode and anode is a top contact that contacts a top surface of the waveguide structure with respect to the growth direction of the waveguide structure; and wherein:
the top contact is provided as a strip having a width that at least partially defines the lateral width of the fundamental mode of the waveguide structure; and/or
the top contact is provided as a strip having a width that extends, at least partially, across the lateral width of the waveguide structure.

18. The device of claim 1, wherein the waveguide structure comprises a ridge formed in a top surface of the waveguide structure with respect to the growth direction, the ridge having a width that defines the lateral width of the fundamental mode of the waveguide structure.

19-20. (canceled)

21. The device of claim 1, wherein the top contact and/or ridge has a width that is substantially constant along its length, or has a width that varies or tapers along at least a portion of its length.

22. The device of claim 1, wherein the waveguide structure further comprises a second end facet, optionally arranged substantially opposite and/or perpendicular to the direction of light propagation in the waveguide structure.

23. The device of claim 1, wherein the top contact and/or ridge extends between the first and second end facets.

24. (canceled)

25. The device of claim 1, wherein the first end facet comprises a coating for reducing the reflectance of the first end facet for the wavelength of the incident light beam; and, optionally or preferably, wherein in the coating is a layered dielectric coating configured to reduce the reflectance of the first end facet to less than 10% for the wavelength of the incident light beam.

26-27. (canceled)

28. The device of claim 1, comprising an array of said waveguide structures arranged on a substrate, wherein each waveguide structure has a cathode and anode connected thereto, and the cathodes and anodes of each respective waveguide structure are electrically connected in series or in parallel.

29. An optical power converting system comprising:
an optical power converter device as defined in claim 1; and
a coupling arrangement configured to couple an incident light beam into the waveguide structure of the power converter device,
wherein the anode and cathode of the power converter device are connectable to an electrical component and configured to provide electrical power to the electrical component.

30. The system of claim 29, wherein the coupling arrangement comprises an optical fiber and/or optical waveguide configured to guide the light beam to the power converter device.

31. The system of claim 29, wherein the coupling arrangement comprises a lens configured to receive an incident light beam and couple the incident light beam into the waveguide structure.

32. (canceled)

33. A photonic integrated circuit comprising an optical power converter device as defined in claim 1 for providing electrical power to the photonic integrated circuit.

34. A method of operating the optical power converter of claim 1 operating in a photovoltaic mode, comprising:
coupling an incident light beam into the waveguide structure;
absorbing the guided light to generate photocarriers and an associated photovoltage;
re-distributing the generated photocarriers and photovoltage over the length of the device; and
extracting photocarriers at the cathode and anode to generate an electrical power output signal.

35-37. (canceled)
